(19) United States
(12) Patent Application Publication
(10) Pub. No.: US 2026/0223388 A1
(43) Pub. Date: Jul. 30, 2026

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventor: Takeshi SUZUKI, Zushi-city, Kanagawa (JP)

(73) Assignee: FUJI ELECTRIC CO., LTD., Kawasaki-shi (JP)

(21) Appl. No.: 19/403,682

(22) Filed: Nov. 28, 2025

(30) Foreign Application Priority Data
Jan. 24, 2025 (JP) 2025-011002

(51) Int. Cl. H10D 30/65; H10D 30/01; H10D 62/10; H10D 62/60; H10D 62/832

(52) U.S. Cl. CPC H10D 30/65; H10D 30/0281; H10D 62/124; H10D 62/60; H10D 62/8325

(57) ABSTRACT

A semiconductor device, including: a semiconductor substrate containing silicon carbide; a gate insulating film containing silicon oxide, provided on a surface of the semiconductor substrate; and a gate electrode provided on a surface of the gate insulating film. The semiconductor device has a plurality of germanium atoms and a plurality of alkaline earth metal atoms at an interface between the gate insulating film and the semiconductor substrate.

### CROSS REFERENCE TO RELATED APPLICATIONS

This application is based upon and claims the benefit of priority of the prior Japanese Patent Application No. 2025-011002, filed on January 24, 2025, the entire contents of which are incorporated herein by reference.

### BACKGROUND OF THE INVENTION

### 1. Field of the Invention

Embodiments of the disclosure relate to a silicon carbide semiconductor device and a method of manufacturing a silicon carbide semiconductor device.

### 2. Description of the Related Art

Japanese Patent No. 6526549 describes a technique in which a gate insulating layer is formed by thermal oxidation of an amorphous silicon film containing an element such as germanium (Ge) or magnesium (Mg), and a threshold value is increased by a fixed negative charge formed by a complex of carbon (C) that diffuses from a surface of a silicon carbide (SiC) layer into the gate insulating layer during the thermal oxidation, an element in the gate insulating layer, and oxygen (O). Published Japanese-Translation of PCT Application, Publication No. 2014-523131 describes a technique for increasing channel mobility by forming an intermediate film containing an alkaline earth metal, the intermediate film being formed between a SiC substrate and a gate oxide film.

### SUMMARY OF THE INVENTION

According to an embodiment of the present disclosure, a semiconductor device includes: a semiconductor substrate containing silicon carbide; a gate insulating film containing silicon oxide, provided on a surface of the semiconductor substrate; and a gate electrode provided on a surface of the gate insulating film. The semiconductor device has a plurality of germanium atoms and a plurality of alkaline earth metal atoms at an interface between the gate insulating film and the semiconductor substrate.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to an embodiment.

FIG. 2 is a flowchart depicting an outline of a method of manufacturing the silicon carbide semiconductor device according to the embodiment.

FIG. 3 is a flowchart depicting an outline of a process at step S3 in FIG. 2.

FIG. 4 is a cross-sectional view of the silicon carbide semiconductor device according to the embodiment during manufacture.

FIG. 5 is a cross-sectional view of the silicon carbide semiconductor device according to the embodiment during manufacture.

FIG. 6 is a cross-sectional view of the silicon carbide semiconductor device according to the embodiment during manufacture.

FIG. 7 is a cross-sectional view of the silicon carbide semiconductor device according to the embodiment during manufacture.

FIG. 8 is a schematic view depicting a state of a SiC surface in FIG. 5.

FIG. 9 is a schematic view depicting a state of the SiC surface in FIG. 6.

FIG. 10 is a schematic view depicting a state of the SiC surface in FIG. 6.

FIG. 11 is a schematic view depicting a state of the SiC surface in FIG. 6.

FIG. 12 is a schematic view depicting a state of the SiC surface in FIG. 6.

FIG. 13 is a schematic view depicting a state of the SiC surface in FIG. 6.

FIG. 14 is a schematic view depicting a state of the SiC surface in FIG. 6.

FIG. 15 is a chemical reaction formula for explaining a behavior of Ge atoms remaining at an SiO_{2/}SiC interface.

FIG. 16 is a schematic view depicting a state of the SiC surface in FIG. 6.

FIG. 17 is a schematic view depicting a state of the SiC surface in FIG. 6.

FIG. 18 is a schematic view depicting a state of the SiC surface in FIG. 6.

FIG. 19 is a schematic view depicting a state of the SiC surface in FIG. 6.

FIG. 20 is a schematic view depicting a state of the SiC surface in FIG. 6.

FIG. 21 is a schematic view depicting a state of a SiO_{2/}SiC interface in FIG. 7.

FIG. 22 is a schematic diagram depicting a structure of general semiconductor manufacturing equipment.

FIG. 23 is a schematic view depicting a structure of a radical generator in FIG. 22.

FIG. 24 is a table depicting binding energy of predetermined bond types.

FIG. 25 is a cross-sectional view depicting another example of a structure of a silicon carbide semiconductor device according to the embodiment.

FIG. 26 is a table depicting results of measuring an interface state density at the SiO_{2/}SiC interface in first and second examples and a first comparison example.

FIG. 27 is a table depicting results of calculation of field-effect mobilities of a third example and a second comparison example by simulation.

FIG. 28 is a flowchart depicting an outline of a method of manufacturing a silicon carbide semiconductor device in a reference example.

### DETAILED DESCRIPTION OF THE INVENTION

First, problems associated with the conventional techniques are discussed. In Japanese Patent No. 6526549, the gate characteristics are adversely affected by fixed negative charge generated in the gate insulating layer when the gate insulating layer is formed. In Published Japanese-Translation of PCT Application, Publication No. 2014-523131, since excess carbon derived from the oxidation of the SiC substrate is taken into the intermediate film and the gate oxide film, the reliability of the gate oxide film may be reduced.

### An overview of an embodiment of the present disclosure is described

(1)A silicon carbide semiconductor device according to one aspect of the present disclosure has the following features. A semiconductor device includes: a semiconductor substrate containing silicon carbide; a gate insulating film provided on a surface of the semiconductor substrate and containing silicon oxide; and a gate electrode provided on a surface of the gate insulating film. Germanium atoms and alkaline earth metal atoms are present at an interface between the gate insulating film and the semiconductor substrate.

According to the above disclosure, excess carbon derived from SiC oxidation is substituted with germanium atoms at the interface between the gate insulating film and the semiconductor substrate, and no excess carbon is present at the interface between the gate insulating film and the semiconductor substrate. Since there is no excess carbon that becomes a hole trap level at the interface between the gate insulating film and the semiconductor substrate, Coulomb scattering due to charge of holes does not occur, and as a result, a decrease in channel mobility (field-effect mobility μ_{FE}) may be prevented. According to the above disclosure, a portion of the germanium atoms at the interface between the gate insulating film and the semiconductor substrate are substituted with alkaline earth metal atoms, and the density of germanium atoms that become an electron trap level in the gate insulating film is reduced as much as possible. Thus, increases in the interface state density at the interface between the gate insulating film and the semiconductor substrate may be suppressed, whereby adverse effects on the gate characteristics (deterioration in the long-term reliability of the gate insulating film and variation of the gate threshold voltage) may be suppressed, and the reliability of the silicon carbide semiconductor device may be improved.

(2) In the silicon carbide semiconductor device according to the present disclosure, in (1) described above, the density of the germanium atoms at the interface between the gate insulating film and the semiconductor substrate may be 1×10⁸ atoms/cm² or more but not more than 1×10¹² atoms/cm².

According to the above disclosure, even when germanium atoms at the interface between the gate insulating film and the semiconductor substrate become an electron trap level, gate characteristics are not adversely affected.

(3) In the silicon carbide semiconductor device according to (1) or (2) above, a density of the alkaline earth metal atoms at an interface between the gate insulating film and the semiconductor substrate may be 1×10¹¹ atoms/cm² or more but not more than 1×10¹³ atoms/cm².

According to the above disclosure, the density of germanium atoms at the interface between the gate insulating film and the semiconductor substrate is low enough not to adversely affect the gate characteristics.

(4) In the silicon carbide semiconductor device according to any one of (1) to (3) above, the germanium atoms at the interface between the gate insulating film and the semiconductor substrate may form an oxide or an oxynitride in the gate insulating film.

According to the above disclosure, germanium atoms at the interface between the gate insulating film and the semiconductor substrate are assimilated (incorporated) with the gate insulating film, and the insulating properties of the gate insulating film are maintained.

(5) In the silicon carbide semiconductor device according to any one of (1) to (4) above, the alkaline earth metal atoms at the interface between the gate insulating film and the semiconductor substrate may form an oxide in the gate insulating film.

According to the above disclosure, the alkaline earth metal atoms at the interface between the gate insulating film and the semiconductor substrate are assimilated with the gate insulating film, and the insulating properties of the gate insulating film are maintained. In addition, the alkaline earth metal atoms at the interface between the gate insulating film and the semiconductor substrate become an oxide and have a large band gap, and hardly allow electrons to flow. Therefore, the alkaline earth metal atoms do not become a trap level. Therefore, it is possible to prevent an increase in the interface state density at the interface between the gate insulating film and the semiconductor substrate.

(6) Further, in the silicon carbide semiconductor device according to the present disclosure, in any one of (1) to (5) described above, the interface between the gate insulating film and the semiconductor substrate is free of excess carbon.

According to the above disclosure, since the interface state density at the interface between the gate insulating film and the semiconductor substrate may be reduced, the gate characteristics may be prevented from being adversely affected by excess carbon.

(7) In addition, the silicon carbide semiconductor device according to the present disclosure includes, in any one of (1) to (6) described above, a first semiconductor region of a first conductivity type provided in the semiconductor substrate, a second semiconductor region of a second conductivity type provided between a front surface of the semiconductor substrate and the first semiconductor region, and a third semiconductor regions of the first conductivity type selectively provided between the front surface of the semiconductor substrate and the second semiconductor region. The gate insulating film is provided in contact with a region of the second semiconductor region between the third semiconductor regions and the first semiconductor region. The gate electrode may be provided facing the second semiconductor region with the gate insulating film intervening therebetween.

Accordingly, the above disclosure is applicable to a silicon carbide semiconductor device having an insulated gate structure.

(8) In the silicon carbide semiconductor device according to any one of (1) to (7) described above, the alkaline earth metal atoms may be magnesium atoms.

According to the above disclosure, since the vapor pressure of magnesium is very high, even when the carbon atoms deposited on the surface of the semiconductor substrate are heated to a temperature of about 350 degrees C or more but not more than 450 degrees C in a removing process, sufficient vapor of magnesium (large excess flux amount of magnesium irradiation) may be easily obtained.

(9) A method of manufacturing a silicon carbide semiconductor device according to one aspect of the present disclosure is as follows. The method includes a predetermined process of oxidizing a surface of a semiconductor substrate containing silicon carbide, a removing process of removing carbon atoms precipitated on the surface of the semiconductor substrate in the predetermined process, a first forming process of depositing a gate insulating film containing silicon oxide on the surface of the semiconductor substrate from which the carbon atoms have been removed, and a second forming process of forming a gate electrode on a surface of the gate insulating film. The removing process includes a first removing process of desorbing the carbon atoms from the surface of the semiconductor substrate by first irradiating the surface of the semiconductor substrate with nitrogen atoms having unpaired electrons (first irradiation), and a second removing process of desorbing the carbon atoms remaining on the surface of the semiconductor substrate after the first removing process by performing a first process of depositing germanium atoms on the surface of the semiconductor substrate and a second process of irradiating the surface of the semiconductor substrate with nitrogen atoms having unpaired electrons (second irradiation).

According to the above disclosure, before the deposition of the gate insulating film, all the excess carbon at the surface of the semiconductor substrate may be removed by recombination of bonds among the excess carbon (carbon atoms) precipitated at the surface of the semiconductor substrate, the nitrogen atoms irradiated to the surface of the semiconductor substrate in the second removing process, and the germanium atoms deposited on the surface of the semiconductor substrate in the second removing process. By depositing the gate insulating film after removing all excess carbon at the surface of the semiconductor substrate in advance, excess carbon does not remain at the interface between the gate insulating film and the semiconductor substrate. Since there is no excess carbon that becomes a hole trap level at the interface between the gate insulating film and the semiconductor substrate, decreases in channel mobility may be prevented.

(10) In the method of manufacturing the silicon carbide semiconductor device according to the present disclosure, in (9) described above, in the first removing process, the semiconductor substrate may be heated at a temperature of 500 degrees C or more but not more than 800 degrees C.

According to the above disclosure, the desorption of carbon atoms in the first removing process may be promoted.

(11) In the method of manufacturing the silicon carbide semiconductor device according to (9) or (10) described above, in the second removing process, the semiconductor substrate may be heated at a temperature of 500 degrees C or more but not more than 800 degrees C.

According to the above disclosure, desorption of carbon atoms in the second removing process may be promoted.

(12) In the method of manufacturing the silicon carbide semiconductor device according to the present disclosure, in any one of (9) to (11) described above, in the second removing process, a set of the first process and the second process may be performed multiple times so that a density of the germanium atoms remaining at the surface of the semiconductor substrate is within a range of 1×10¹¹ atoms/cm² to 1×10¹² atoms/cm².

According to the above disclosure, all carbon atoms remaining at the surface of the semiconductor substrate after the first removing process may be removed in the second removing process.

(13) In the method of manufacturing the silicon carbide semiconductor device according to any one of (9) to (12) described above, the removing process may further include a third removing process of removing the germanium atoms at the surface of the semiconductor substrate by depositing alkaline earth metal atoms on the surface of the semiconductor substrate after the second removing process.

According to the above disclosure, the density of germanium atoms at the surface of the semiconductor substrate may be reduced by recombination of bonds between germanium atoms remaining at the surface of the semiconductor substrate after the second removing process, nitrogen atoms at the surface of the semiconductor substrate after the second removing process, and the alkaline earth metal atoms deposited on the surface of the semiconductor substrate in the third removing process before deposition of the gate insulating film. The density of germanium atoms remaining at the interface between the gate insulating film and the semiconductor substrate may be reduced to such an extent that gate characteristics are not adversely affected even when the germanium atoms become electron trap levels. Therefore, the reliability of the silicon carbide semiconductor device may be improved.

(14) In the method of manufacturing the silicon carbide semiconductor device according to (13) described above, the alkaline earth metal atoms may be magnesium atoms.

According to the above disclosure, since the vapor pressure of magnesium is very high, even in a case of heating to a temperature of about 350 degrees C or more but not more than 450 degrees C in the third removing process, sufficient vapor of magnesium (large excess flux amount of magnesium irradiation) may be easily obtained.

(15) In the method of manufacturing the silicon carbide semiconductor device according to the present disclosure, in (14) described above, in the third removing process, the magnesium atoms may be supplied to the surface of the semiconductor substrate in a supply amount exceeding a vapor deposition amount of the magnesium atoms on the surface of the semiconductor substrate.

According to the above disclosure, recombination of bonds among germanium atoms remaining at the surface of the semiconductor substrate after the second removing process, nitrogen atoms at the surface of the semiconductor substrate after the second removing process, and magnesium atoms deposited on the surface of the semiconductor substrate in the third removing process is promoted. Thus, the density of germanium atoms remaining at the surface of the semiconductor substrate may be reduced to such an extent that the gate characteristics are not adversely affected, and the density of magnesium atoms remaining at the surface of the semiconductor substrate may be reduced.

(16) Further, in the method of manufacturing the silicon carbide semiconductor device according to the present disclosure, in (14) or (15) described above, in the third removing process, the semiconductor substrate may be heated at a temperature of 1000 degrees C or more but not more than 1100 degrees C.

According to the above disclosure, vaporization of germanium atoms in the third removing process may be promoted.

(17) The method of manufacturing the silicon carbide semiconductor device according to the present disclosure may further include, in any one of (9) to (16) described above, a heat treatment of oxynitriding the interface between the gate insulating film and the semiconductor substrate by a heat treatment after the first forming process but before the second forming process.

According to the above disclosure, the germanium atoms and the alkaline earth metal atoms at the interface between the gate insulating film and the semiconductor substrate may be assimilated with the gate insulating film, so that the insulating property of the gate insulating film is maintained. In addition, the alkaline earth metal atoms at the interface between the gate insulating film and the semiconductor substrate become an oxide and have a large band gap, and hardly emit electrons, and thus do not become a trap level. Therefore, increases in the interface state density at the interface between the gate insulating film and the semiconductor substrate may be prevented.

(18) In the method of manufacturing the silicon carbide semiconductor device according to the present disclosure, in any one of (14) to (17) described above, in the first removing process, a first functional group is desorbed from the surface of the semiconductor substrate by an electromigration phenomenon of the first functional group due to a covalent bond between the carbon atom and the nitrogen atom subjected to the first irradiation. In the second removing process, a second functional group may be desorbed from the surface of the semiconductor substrate by an electromigration phenomenon of the second functional group due to a covalent bond between the germanium atom and the nitrogen atom subjected to the second irradiation.

According to the above disclosure, in the first and second removing processes, the excess carbon at the surface of the semiconductor substrate may be removed by utilizing the electromigration phenomenon of the first and second functional groups.

(19) In the method of manufacturing the silicon carbide semiconductor device according to the present disclosure, in (18) described above, in the third removing process, the second functional group may be reduced by the magnesium atoms to vaporize and remove the germanium atoms whose bonds with the nitrogen atoms are broken.

According to the above disclosure, in the third removing process, the germanium atoms at the surface of the semiconductor substrate may be removed using the difference of the binding energy between the magnesium atoms and the nitrogen atoms and the binding energy between the germanium atoms and the nitrogen atoms.

Findings underlying the present disclosure are discussed. A method of manufacturing the silicon carbide semiconductor device of a reference example will be described. FIG. 28 is a flowchart depicting an outline of a method of manufacturing the silicon carbide semiconductor device in the reference example. First, a SiC region constituting a predetermined element structure is formed by epitaxial growth of silicon carbide (SiC) or ion implantation in a SiC surface region (step S101). Next, the SiC surface is cleaned by hydrogen (H₂₎ etching, sacrificial oxidation, or the like (step S102). Next, a silicon oxide (SiO₂₎ film constituting gate insulating films is deposited on the SiC surface (step S103).

In the wafer cleaning performed during the process at step S101 or the process at step S102, the SiC surface is oxidized, and carbon (C) atoms constituting SiC are desorbed and segregated at the interface between the SiO₂ film and SiC (hereinafter, referred to as SiO_{2/}SiC interface). The excess carbon is taken into the SiO₂ film and becomes a hole trap level, whereby the channel mobility decreases. In addition, crystal defects (interface states) at the SiO_{2/}SiC interface cause a decrease in long-term reliability of the gate insulating film, variations in gate threshold voltage, and the like.

Thus, crystal defects caused by excess carbon at the SiO_{2/}SiC interface are reduced by a heat treatment (oxynitriding annealing) using nitrogen monoxide (NO) gas or dinitrogen monoxide (N₂O) gas (step S104). Thereafter, a gate electrode and a surface electrode are formed at the SiC surface (steps S105 and S106) thereby completing the silicon carbide semiconductor device of the reference example. However, even when the process at step S104 is performed, it cannot be said that the excess carbon at the SiO_{2/}SiC interface is sufficiently reduced, and there is room for improvement.

Thus, there is a problem in that excess carbon at the SiO_{2/}SiC interface decreases channel mobility. Preferably, the reliability of the silicon carbide semiconductor device may be improved by suppressing an adverse effect on the gate characteristics caused by the interface state of the SiO_{2/}SiC interface.

Hereinafter, embodiments of a silicon carbide semiconductor device and a method of manufacturing a silicon carbide semiconductor device according to the present disclosure are described in detail with reference to the accompanying drawings. In the present description and the accompanying drawings, layers and regions prefixed with n or p mean that majority carriers are electrons or holes, respectively. Further, + and − appended to n and p mean that the dopant concentration is higher and lower, respectively, than layers and regions without + and −. In the following description of the embodiments and the accompanying drawings, the same components are denoted by the same reference numerals, and redundant description thereof is omitted.

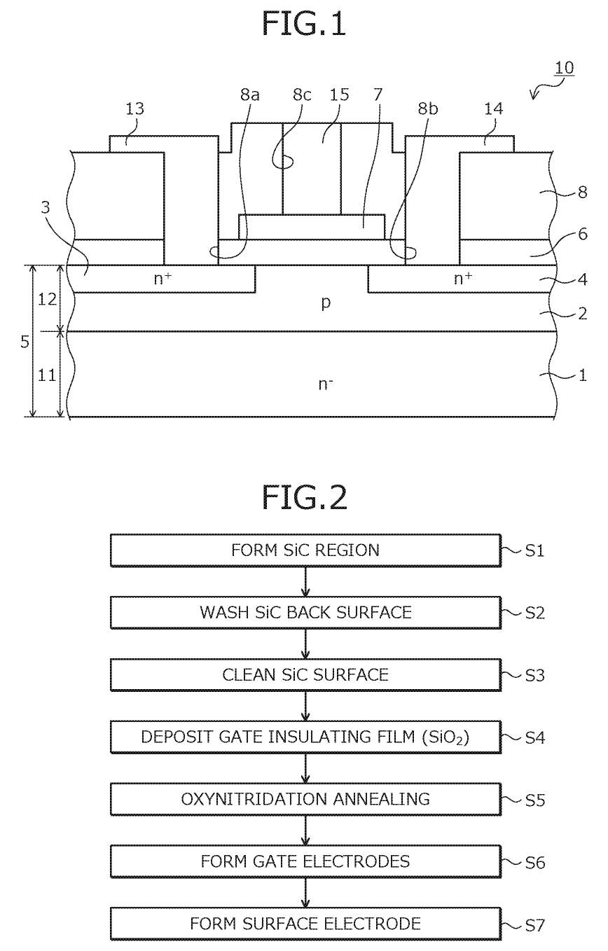

A silicon carbide semiconductor device according to an embodiment is described below. FIG. 1 is a cross-sectional view depicting a structure of a silicon carbide semiconductor device according to an embodiment. A silicon carbide semiconductor device 10 according to the embodiment depicted in FIG. 1 is a planar (that is, planar gate type) metal oxide semiconductor field effect transistor (MOSFET) including insulated gates having a three-layer structure of metal-oxide film-semiconductor), includes gate electrodes 7 at a front surface of a semiconductor substrate 5 via gate insulating films 6, and germanium (Ge) atoms and magnesium (Mg) atoms are present at an interface (SiO_{2/}SiC interface) between the gate insulating films 6 and the semiconductor substrate 5.

The semiconductor substrate 5 is a semiconductor chip formed by growing by epitaxy an epitaxial layer 11 containing n⁻-type silicon carbide (SiC) and an epitaxial layer 12 containing p-type SiC in this order. The epitaxial layers 11 and 12 constitute an n⁻-type region (first semiconductor region) 1 and a p-type region (second semiconductor region) 2, respectively. The semiconductor substrate 5 has, as a front surface, a first main surface having the epitaxial layer 12 and, as a back surface, a second main surface having the epitaxial layer 11. A starting substrate (bulk substrate, not depicted) containing SiC used at the time of epitaxial growth of the epitaxial layers 11 and 12 may remain at the back surface of the semiconductor substrate 5. The epitaxial layer 11 itself may be the starting substrate.

Between the front surface of the semiconductor substrate 5 and the p-type region 2, n⁺-type source regions (third semiconductor regions) 3 and n⁺-type drain regions 4 are selectively provided apart from each other so as to be exposed at the front surface of the semiconductor substrate 5 and in contact with the p-type region 2. The n⁺-type source regions 3 and the n⁺-type drain regions 4 are diffused regions formed by ion implantation in the epitaxial layer 12. A portion of the p-type epitaxial layer 12 excluding the n⁺-type source regions 3 and the n⁺-type drain regions 4 constitutes the p-type region 2. The p-type region 2 reaches the front surface of the semiconductor substrate 5 between the n⁺-type source regions 3 and the n⁺-type drain regions 4 that are adjacent to each other. At the front surface of the semiconductor substrate 5, the gate electrodes 7 are provided via the gate insulating films 6 on portions of the p-type region 2 sandwiched between the n⁺-type source regions 3 and the n⁺-type drain regions 4 that are adjacent to each other.

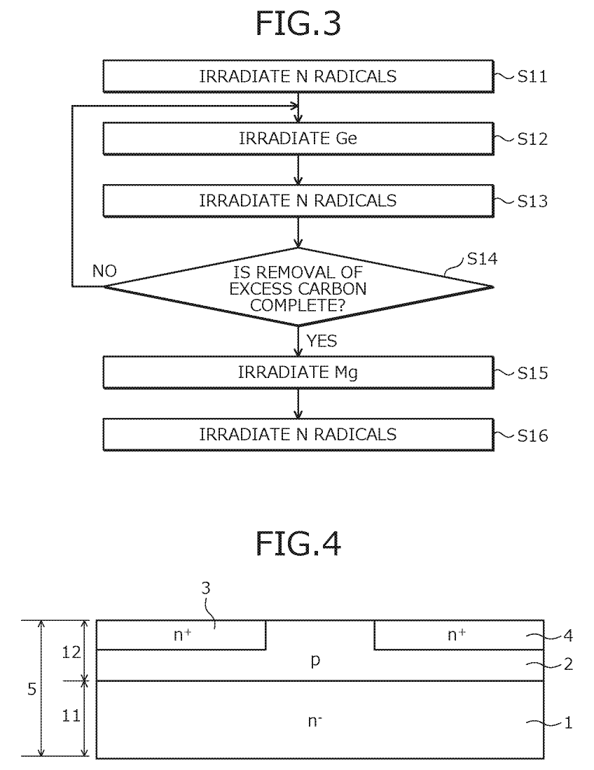

The gate insulating films 6 are formed by a silicon oxide (SiO₂₎ film deposited using a general deposition method. At the interface between the gate insulating films 6 and the semiconductor substrate 5, Ge atoms are present at intervals of about the maximum migration distance of groups containing Ge atoms (more specifically, “—GeN groups”: refer to FIG. 14) generated during processing before the formation of the gate insulating films 6 (processes at steps S12 and S13 described later: refer to FIG. 3). The maximum migration distance of a group (an atomic group that may move as one aggregate during a chemical reaction) is the upper limit of the migration distance of the group due to the electromigration phenomenon. In addition, at the interface between the gate insulating films 6 and the semiconductor substrate 5, Mg atoms are present at such intervals that collision between groups containing Mg atoms (more specifically, “—MgN groups”: refer to FIG. 19) generated at the time of processing before formation of the gate insulating films 6 (process at step S15 described later: FIG. 3) does not occur.

At the interface between the gate insulating films 6 and the semiconductor substrate 5, the density of Ge atoms (the number of atoms per unit area) is lower than the density of Mg atoms and is, for example, about 1×10⁸ atoms/cm² or more but not more than 1×10¹² atoms/cm² (preferably may be about 1×10⁹ atoms/cm² or less). The density of Mg atoms at the interface between the gate insulating films 6 and the semiconductor substrate 5 is, for example, about 1×10¹¹ atoms/cm² or more but not more than 1×10¹³ atoms/cm². Ge atoms at the interface between the gate insulating films 6 and the semiconductor substrate 5 constitute (generate) an oxide or an oxynitride in the gate insulating films 6 and are assimilated (incorporated) with the gate insulating films 6. The Mg atoms at the interface between the gate insulating films 6 and the semiconductor substrate 5 form an oxide in the gate insulating films 6 and are assimilated (incorporated) with the gate insulating films 6. There is no excess carbon at the interface between the gate insulating films 6 and the semiconductor substrate 5. Excess carbon is a single C atom that is disconnected from a silicon (Si) atom constituting SiC (material of the semiconductor substrate 5) or an aggregate in which single C atoms are bonded to each other.

The interlayer insulating film 8 is provided on the entire front surface of the semiconductor substrate 5 and covers the gate electrodes 7. The gate insulating films 6 may extend between the semiconductor substrate 5 and the interlayer insulating film 8. The interlayer insulating film 8 may also serve as a field oxide film (not depicted). The field oxide film is disposed between the front surface of the semiconductor substrate 5 and the interlayer insulating film 8 (or between the gate insulating films 6 and the interlayer insulating film 8) in the entire region (not depicted) excluding an active region (a region in which cells (functional units) of the MOSFET are disposed). Contact holes 8a and 8b penetrate through the interlayer insulating film 8 and the gate insulating films 6 in the depth direction and reach the semiconductor substrate 5. Contact holes 8c penetrate through the interlayer insulating film 8 in the depth direction and reach the gate electrodes 7.

The n⁺-type source regions 3 and the n⁺-type drain regions 4 are exposed in the contact holes 8a and 8b, respectively. Extended portions of the gate electrodes 7 are exposed in the contact holes 8c. The gate electrodes 7 are formed by, for example, a polysilicon (poly-Si) layer. Extending portions (gate polysilicon wiring layer) of the gate electrodes 7 functions as a gate finger constituting a coupling portion with a gate pad (not depicted). The source electrode 13 is in ohmic contact with the n⁺-type source regions 3 in the contact holes 8a. The drain electrode 14 is in ohmic contact with the n⁺-type drain regions 4 in the contact holes 8b. The gate metal wiring layer 15 is formed on the extending portion of the gate electrodes 7 in the contact hole 8c, and functions as a gate finger.

The source electrode 13 and the drain electrode 14 have a stacked structure in which, for example, an ohmic electrode film, a barrier metal, and an electrode film containing aluminum (Al) (hereinafter referred to as an Al electrode film) are stacked in this order. The gate metal wiring layer 15 and the gate pad are Al electrode films. The ohmic electrode film is, for example, a nickel silicide (NixSiy, x and y are positive numbers) film and is in ohmic contact with the front surface of the semiconductor substrate 5. The barrier metal is, for example, a titanium (Ti) film and has a function of preventing atom diffusion and mutual reaction between regions facing each other across the barrier metal intervening therebetween or between metals. The Al electrode film is an Al film or an Al alloy film. The outermost surface of the front surface of the semiconductor substrate 5 is covered with a passivation film (not depicted).

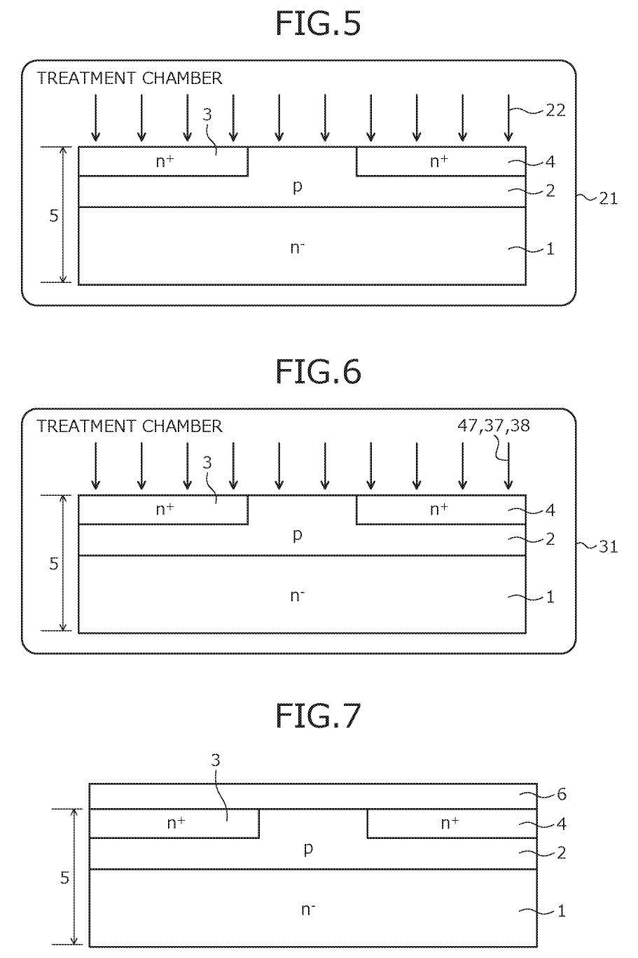

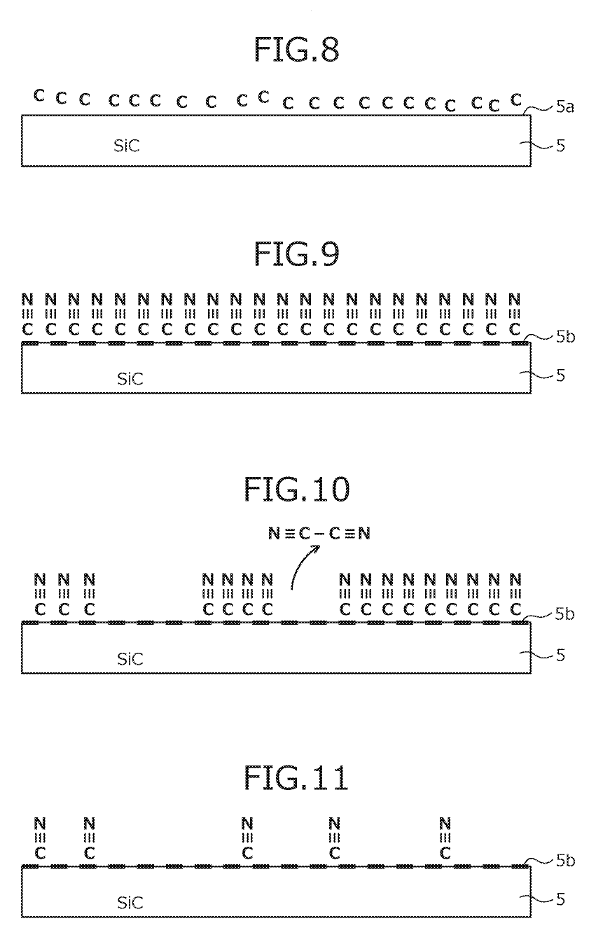

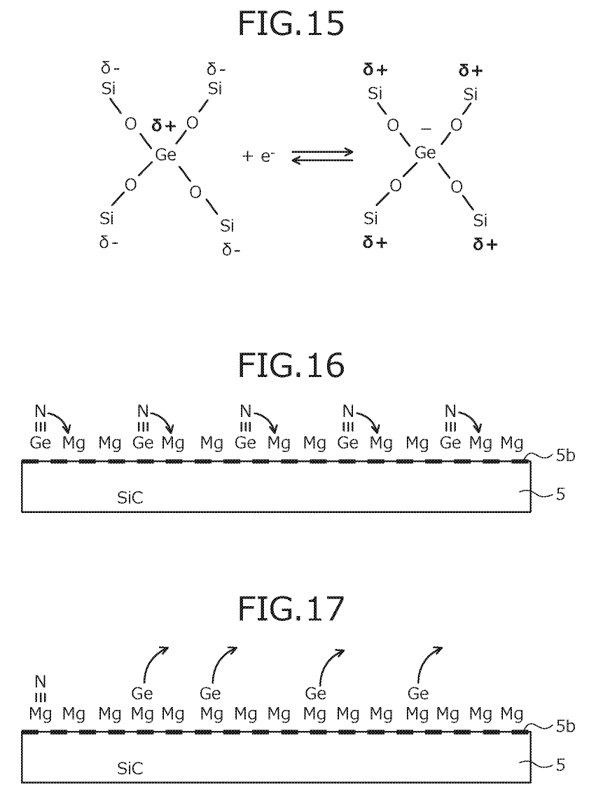

A method of manufacturing the silicon carbide semiconductor device according to the embodiment will be described. FIG. 2 is a flowchart depicting an outline of a method of manufacturing the silicon carbide semiconductor device according to the embodiment. FIG. 3 is a flowchart depicting an outline of a process at step S3 in FIG. 2. FIGS. 4, 5, 6, and 7 are cross-sectional views of the silicon carbide semiconductor device according to the embodiment during manufacture. FIGS. 4 to 7 depict, respectively, states during the processes at steps S1 to S4 in FIG. 2. FIG. 8 is a schematic view depicting the state of the SiC surface in FIG. 5. FIGS. 9, 10, 11, 12, 13, 14, 16, 17, 18, 19, and 20 are schematic views depicting states of the SiC surface in FIG. 6. FIG. 15 is a chemical reaction formula for explaining the behavior of Ge atoms remaining at the SiO_{2/}SiC interface. FIG. 21 is a schematic view depicting the state of the SiO_{2/}SiC interface in FIG. 7.

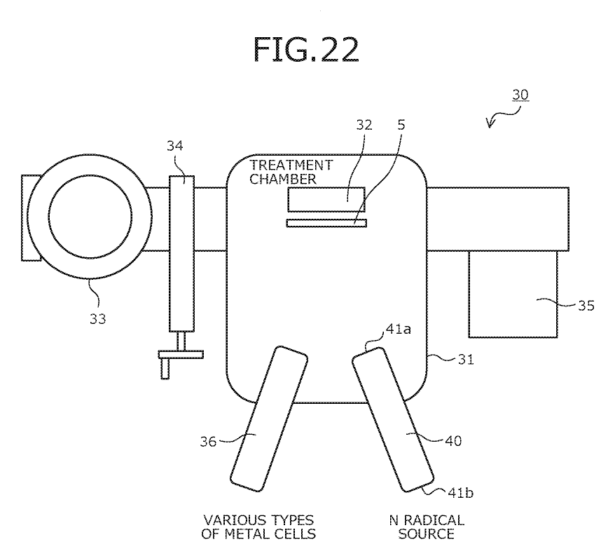

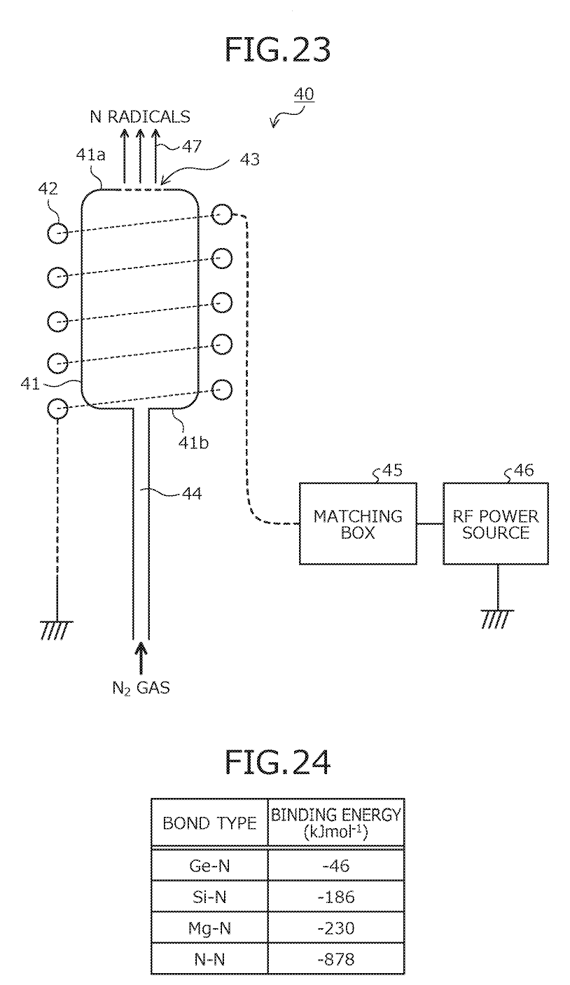

In FIGS. 8 to 21, in order to clarify the state of the front surface (SiC front surface) of the semiconductor substrate 5, the thickness of the semiconductor substrate 5 is simplified and depicted thinly, and the internal structure of the semiconductor substrate 5 is not depicted. In FIGS. 8 to 21, a step (step portion: not depicted), a terrace (atomic-level flat portion sandwiched between adjacent steps), and a kink (connecting portion between two steps: not depicted) structure of the SiC surface are depicted in a simplified manner. FIG. 22 is a schematic diagram depicting a structure of general semiconductor manufacturing equipment. FIG. 23 is a schematic view depicting a structure of the radical generator (radical source) in FIG. 22. FIG. 24 is a table depicting binding energy (energy necessary to separate a covalent bond of 1 mol of a substance) of predetermined bond types.

First, as depicted in FIG. 4, on a front surface of an n-type starting substrate (starting wafer: not depicted) containing SiC, the n⁻-type epitaxial layer 11 doped with, for example, nitrogen (N) and constituting the n⁻-type region 1 and a p-type epitaxial layer 12 doped with, for example, Al and constituting the p-type region 2 are grown by epitaxy in this order to fabricate the semiconductor substrate (SiC substrate) 5. The semiconductor substrate 5 may be obtained by removing the starting substrate by grinding from the back surface thereof to a position corresponding to a product thickness used for the silicon carbide semiconductor device, or may be obtained by leaving the starting substrate. The n⁻-type region 1 may be constituted by an n⁻-type starting substrate. The semiconductor substrate 5 has, as the front surface, a first main surface having the p-type epitaxial layer 12 and, as the back surface, a second main surface having the n⁻-type epitaxial layer 11.

Next, by photolithography and ion implantation of an dopant of a predetermined conductivity type, diffused regions (hereinafter, referred to as SiC regions) of the predetermined conductivity type such as the n⁺-type source regions 3 and the n⁺-type drain regions 4 are formed in regions of the semiconductor substrate 5, at the front surface thereof (step S1 (predetermined process) in FIG. 2). In the ion implantation for forming the SiC region, for example, phosphorus (P) may be used as an n-type dopant and, for example, Al may be used as a p-type dopant. The n⁻-type semiconductor substrate 5 may be prepared, and the p-type region 2 may be selectively formed in the semiconductor substrate 5 by ion implantation in the process at step S1. In this case, a portion of the n⁻-type semiconductor substrate 5 excluding the p-type region 2, the n⁺-type source regions 3, and the n⁺-type drain regions 4 constitutes the n⁻-type region 1.

A cleaning process such as RCA cleaning (wet cleaning using a mixed acid of a strong acid and a strong base) is performed between the various steps of the process at step S1 to thereby remove organic substances, particles, ion contamination, and the like generated in the various steps and to thereby pass the cleaned semiconductor substrate 5 to the manufacturing line of the next step. The semiconductor substrate 5 is oxidized by being exposed to the atmosphere or being immersed in a cleaning liquid (acidic solution). At the front surface (SiC surface) of the semiconductor substrate 5, a crystal defect structure containing oxygen (O) atoms and excess carbon is generated due to SiC oxidation. Therefore, the front surface of the semiconductor substrate 5 is cleaned by etching 22, and the crystal defect structure is removed together with the surface layer of the semiconductor substrate 5 at the front surface thereof (step S2 in FIG. 2, FIG. 5 (predetermined process)).

The etching 22 in the process at step S2 is, for example, H₂ etching performed in a state where the semiconductor substrate 5 is exposed to a gas atmosphere containing hydrogen (H₂) gas at a purity of about 3% to 100% and the semiconductor substrate 5 is heated to a temperature of about 1300 degrees C or more but not more than 1500 degrees C in a treatment chamber 21 of the general etching equipment. When the gas atmosphere of the H₂ etching is a mixed gas atmosphere containing a gas other than the H₂ gas, the gas other than the H2 gas is a rare gas that is less likely to react with other atoms, such as argon (Ar), neon (Ne), or krypton (Kr), so that the semiconductor substrate 5 may be etched 22 without oxidation, and reoxidation of the front surface of the semiconductor substrate 5 may be suppressed. The gas atmosphere of the H₂ etching may be preferably set to, for example, a pressure of about 0.5 Torr or more but not more than 760 Torr, and a gas flow rate of about 100 sccm or more depending on the processing capability (exhaust capability) of the etching equipment.

The etching 22 in the process at step S2 may be H₂ plasma etching instead of H₂ etching. When the etching 22 in the process at step S2 is H₂ plasma etching, the front surface of the semiconductor substrate 5 is etched 22 by, for example, inserting the semiconductor substrate 5 into the treatment chamber 21 of a general plasma treatment equipment and exposing the front surface of the semiconductor substrate 5 to H₂ plasma generated using H₂ gas as a source gas or irradiating the front surface of the semiconductor substrate 5 with active species (radicals or ions) of hydrogen (H) in the H₂ plasma. At this time, after the semiconductor substrate 5 is inserted into the treatment chamber 21, the inside of the treatment chamber 21 is evacuated and depressurized (preferably, for example, vacuum evacuation to about 0.05 Pa or less) to reduce the amount of O₂ in the treatment chamber 21 as much as possible, and then H₂ plasma may be generated.

The H₂ plasma may be generated after the treatment chamber 21 is evacuated two or three times. In this case, for example, after the inside of the treatment chamber 21 is vacuum-exhausted, introduction of a rare gas such as Ar into the treatment chamber 21 and vacuum exhaust of the inside of the treatment chamber 21 are alternately repeated and then H₂ plasma is generated. Thus, the H₂ plasma etching may be performed after reducing the amount of residual O₂ or moisture (H₂O) in the treatment chamber 21. The pressure in the treatment chamber 21 may be, for example, in a range of about 1 Pa to 100 Pa, which is a typical pressure range. H₂ plasma may be generated by using a general plasma generation technique such as capacitively coupled plasma (CCP), inductively coupled plasma (ICP), or electron cyclotron resonance (ECR) plasma.

The H₂ plasma by the CCP plasma is generated using an radio frequency (RF) power source of a general band (for example, 13.56 MHz). The H₂ plasma by the ICP plasma is generated by causing an RF current of 13.56 MHz, 27.12 MHz, or 40.68 MHz to flow through a coil wound around a hollow cylindrical discharge tube to thereby generate an electric field by electromagnetic induction in the discharge tube, and ionizing a part of the H₂ gas in the discharge tube by collisions with electrons generated in the discharge tube by RF discharge in the coil and accelerated by the electric field in the discharge tube. H₂ plasma by ECR plasma is generated using microwaves (2.45 GHz). As a source gas of the H₂ plasma, a H₂ gas having a purity of 100% may be used, or a H₂ gas diluted with a rare gas such as Ar may be used.

The etching 22 in the process at step S2 may be rare gas plasma etching instead of H₂ etching. The rare gas plasma etching may be performed in a same manner as the H₂ plasma etching except that a rare gas such as Ar, Ne, or Kr is used as a source gas of plasma instead of the H₂ gas. Also in the rare gas plasma etching, reoxidation of the front surface of the semiconductor substrate 5 may be suppressed by using a rare gas that is less likely to react with other atoms. The rare gas plasma etching is sputter etching that etches the surface layer of the front surface of the semiconductor substrate 5 in atomic units by ionizing and colliding a rare gas. Therefore, it is preferable to adjust the discharge power (RF power) for plasma generation and the bias voltage (RF voltage) applied to the semiconductor substrate 5 to avoid excessive ion collision with the front surface of the semiconductor substrate 5.

Damage caused at the front surface of the semiconductor substrate 5 by ion collision in the rare gas plasma etching may be recovered by heating the semiconductor substrate 5 in an atmosphere free of oxygen before the process at step S3 described later. The atmosphere free of oxygen is a state in which the inside of the treatment chamber 21 is vacuum-exhausted or a state in which the inside of the treatment chamber 21 is filled with an inert gas such as Ar gas or is an inert gas atmosphere containing hydrogen gas. This heat treatment may be performed, for example, at a temperature of 800 degrees C or higher at which a damage recovery effect of the SiC surface is obtained but not higher about 1000 degrees C at which deposition of graphene (excess carbon) due to Si sublimation does not occur. In the process at step S2, after the H₂ etching, sacrificial oxidation of the front surface of the semiconductor substrate 5 may be further performed in a mixed gas atmosphere containing carbon tetrafluoride (CF₄₎ and oxygen (O₂₎.

Next, as depicted in FIG. 6, the front surface of the semiconductor substrate 5 is cleaned in the treatment chamber 31 in a vacuum-exhausted state (atmosphere free of oxygen) (step S3 (removing process) in FIG. 2). The process at step S3 will be described with reference to FIGS. 3 and 8 to 23. The front surface (SiC surface) of the semiconductor substrate 5 is oxidized during the process at step S2 described above or during the conveyance of the semiconductor substrate 5, excess carbon derived from SiC oxidation is precipitated, and the front surface becomes a Si-rich surface 5a having a relatively large number of silicon (Si) atoms (FIG. 8). The excess carbon at the front surface of the semiconductor substrate 5 is taken into the gate insulating films 6 and becomes a hole trap level. Therefore, before the process at step S4 (deposition of the gate insulating films 6) described later, excess carbon at the front surface of the semiconductor substrate 5 is removed by the process at step S3.

Here, a case where excess carbon (indicated by “C” in FIG. 8) is present at a high density over substantially the entire front surface of the semiconductor substrate 5 will be described as an example. However, even in a case where excess carbon is partially present at the front surface of the semiconductor substrate 5, the effect of the process at step S3 may be obtained. In the process at step S3, first, the semiconductor substrate 5 is inserted into the treatment chamber 31 via the load lock chamber (preliminary vacuum chamber) 33 upstream to the treatment chamber 31 so that the treatment chamber 31 of the vacuum apparatus 30 is not opened to the atmosphere (refer to FIG. 22). Then, with the treatment chamber 31 in an evacuated state, the front surface of the semiconductor substrate 5 heated by a heating unit 32 such as a heater is irradiated (first irradiation) 47 with atomic nitrogen (N) radicals (N atoms having unpaired electrons) generated in the discharge tube 41 (refer to FIG. 23) of a radical generator 40, thereby nitriding the front surface of the semiconductor substrate 5 (step S11 (first removing process) in FIG. 3).

The vacuum apparatus 30 includes, in a treatment chamber 31, the heating unit 32 such as a heater for heating the semiconductor substrate 5, multiple metal cells 36 (FIG. 22 depicts one metal cell 36 in a simplified manner) as evaporation sources, and a radical generator 40 for generating atomic N radicals. The inside of the treatment chamber 31 is maintained at a predetermined pressure by controlling the opening and closing of a gate valve 34 between the treatment chamber 31 and the load lock chamber 33 and operation control of a vacuum exhaust unit 35 such as a pump at a subsequent stage of the treatment chamber 31. After the gas atmosphere in the treatment chamber 31 is set to a predetermined pressure by controlling the exhaust rate by the vacuum exhaust unit 35, the N radical irradiation 47 may be performed in the treatment chamber 31. As the number of radical generators 40 is increased, the flux (total magnetic flux) amount of the N radical irradiation 47 is increased, whereby a predetermined irradiation amount (total supply amount) may be obtained in a short time.

The radical generator 40 is a so-called ICP plasma source in which an RF power supply 46 is coupled to a coil 42 wound around a hollow cylindrical discharge tube 41 having a diameter of, for example, about 30 nm to 50 nm via a matching box (impedance matching circuit) 45 for maximizing power transmission from the RF power supply 46 into the discharge tube 41 (FIG. 23). N radicals (active species of N in N₂ plasma) by ICP plasma are generated by flowing an RF current of, for example, 13.56 MHz through the coil 42 wound around the discharge tube 41 to generate an electric field by electromagnetic induction in the discharge tube 41, and ionizing nitrogen (N₂₎ gas in the discharge tube 41 by collisions with electrons generated in the discharge tube 41 by RF discharge in the coil 42 and accelerated by the electric field in the discharge tube 41.

A material of the discharge tube 41 is, for example, pyrolytic boron nitride (PBN). One end 41a of the discharge tube 41 is an open end, and the discharge tube 41 has openings 43 constituting discharge ports for N radicals into the treatment chamber 31 during the N radical irradiation 47. The other end 41b of the discharge tube 41 is a supply port for N₂ gas, which is a source gas of N radicals, and the other end 41b is coupled to a gas supply source (not depicted) via a gas tube (pipe) 44. The flow rate of the N₂ gas introduced into the discharge tube 41 is, for example, about 1.5 standard cubic centimeter per minute (sccm). The coil 42 is, for example, a copper (Cu) pipe having a hollow portion through which cold water flows. The power supplied from the RF power supply 46 into the discharge tube 41 is, for example, about 500 W.

Instead of the ICP plasma source, the radical generator 40 may be an ECR plasma source that generates N radicals by causing a direct current to flow through the coil 42 wound around the hollow cylindrical discharge tube 41 to generate a magnetic field in the discharge tube 41 and supplying microwaves (for example, about 2.45 GHz) to the magnetic field in the discharge tube 41 to cause a resonance phenomenon. By adjusting the plasma conditions using the ICP plasma source or the ECR plasma source, the electron density in the discharge tube 41 may be increased, and substantially all of the N₂ gas in the discharge tube 41 may be ionized into atomic N radicals. More specifically, the flux amount of the N radical irradiation 47 may be set within a range of, for example, about 1.0×10¹⁵/cm²sec or more but not more than 5.0×10¹⁵/cm²sec.

During the process at step S11, the semiconductor substrate 5 may be heated at a temperature in a range of, for example, about 500 degrees C or more but not more than 800 degrees C at which the electromigration of the cyano group is likely to occur. For example, when the heating temperature of the semiconductor substrate 5 is set to about 800 degrees C and the flux amount of the N radical irradiation 47 is set to about 1.2×10¹⁵/cm²sec, the entire front surface of the semiconductor substrate 5 is nitrided in about one second. The irradiation amount of the N radical irradiation 47 may be increased by increasing the number of radical generators 40 and the irradiation time of the N radical irradiation 47. By the process at step S11, excess carbon at the front surface of the semiconductor substrate 5 is nitrided and becomes a cyano group (—CN group (a group in which a C atom and an N atom are bonded by a triple bond): first functional group). Therefore, substantially the entire front surface of the semiconductor substrate 5 becomes a nitrided surface 5b (broken line portion) by the cyano group. Since the Si-rich surface 5a exposed at the front surface of the semiconductor substrate 5 is also nitrided to become the nitrided Si surface 5b, the entire front surface of the semiconductor substrate 5 becomes the nitrided surface 5b (FIG. 9).

The N radical irradiation 47 to the front surface of the semiconductor substrate 5 is further continued under the same conditions from a state in which all the excess carbon at the front surface of the semiconductor substrate 5 is nitrided to become a cyano group. During the N radical irradiation 47 to the front surface of the semiconductor substrate 5, the cyano groups at the front surface of the semiconductor substrate 5 move on the front surface of the semiconductor substrate 5 by electromigration and collide with other nearby cyano groups. The two collided cyano groups immediately react with each other to form a dicyan (NCCN) molecule in which C atoms of the two cyano groups are bonded to each other by a single bond. Since the NCCN molecules are gaseous low molecules (gas molecules) and stay (adsorb) at the surface for a short time, the NCCN molecules are desorbed from the front surface of the semiconductor substrate 5. As the heating temperature of the semiconductor substrate 5 increases, the cyano groups are more likely to collide with each other, and the NCCN molecules are more likely to be desorbed from the front surface of the semiconductor substrate 5. Therefore, the desorption of the NCCN molecules is promoted. The N radical has high reactivity and causes collision between cyano groups even when the temperature of the semiconductor substrate 5 is a normal temperature (for example, about 25 degrees C.). Therefore, the N radical irradiation 47 may be performed while the semiconductor substrate 5 is not heated but kept at room temperature.

By continuing the N radical irradiation 47 to the front surface of the semiconductor substrate 5, the elements of the lower layer exposed by the desorption of the NCCN molecules are nitrided. When the element of the lower layer exposed by the elimination of the NCCN molecule is excess carbon, the excess carbon is nitrided to become a cyano group. The newly generated cyano groups also move on the front surface of the semiconductor substrate 5 by electromigration similarly to the cyano groups generated in the initial stage of the N radical irradiation 47, the newly generated cyano groups collide with other nearby cyano groups, and are desorbed as NCCN molecules. Since the elimination and generation of the NCCN molecules alternately occur repeatedly, the surface density of the cyano groups at the front surface of the semiconductor substrate 5 decreases. When the element of the lower layer exposed by the desorption of the NCCN molecules is Si, the Si (that is, the Si-rich surface 5a) is nitrided to become the nitrided surface 5b (broken line portion) of Si (FIG. 10). In FIG. 10, the desorption of molecules is schematically indicated by arrows. The nitrided Si surface 5b is a silicon nitride (Si₃N₄) surface that forms a mesh-like stable hexagonal crystal structure, and does not form low molecules. Therefore, the nitrided Si surface 5b is maintained in the portion where Si is nitrided.

When the surface density of the cyano groups at the front surface of the semiconductor substrate 5 decreases due to the elimination of the NCCN molecules, the distance between the cyano groups adjacent to each other increases, the collision between the cyano groups does not occur, and the cyano groups remain at the front surface of the semiconductor substrate 5 at intervals of about the maximum migration distance of the cyano groups. At this time, the density of cyano groups remaining at the front surface of the semiconductor substrate 5 is about 1×10¹¹ atoms/cm² or more but not more than 1×10¹² atoms/cm². The irradiation time of the N radical irradiation 47 may be obtained in advance by, for example, simulation or the like such that the cyano groups remain at the front surface of the semiconductor substrate 5 at a density within the above-mentioned range. The front surface of the semiconductor substrate 5 becomes a nitrided surface 5b by the cyano group in a portion where the cyano group remains, and the Si-rich surface 5a exposed by the elimination of the NCCN molecule becomes the nitrided Si surface 5b. The entire front surface of the semiconductor substrate 5 is the nitrided surface 5b (broken line portion) and most of the front surface is the nitrided Si surface 5b (FIG. 11).

Next, a layer of Ge atoms is deposited on the front surface of the semiconductor substrate 5 by irradiating 37 the front surface of the semiconductor substrate 5 with Ge atoms by a vacuum deposition method (step S12 (first process) in FIG. 3). Then, for example, N radical irradiation (second irradiation) 47 is performed on the front surface of the semiconductor substrate 5 by the same method and under the same conditions as in the process at step S11 (step S13 (second process) in FIG. 3). The processes at steps S12 and S13 are performed in a state where the semiconductor substrate 5 is heated at the same temperature as that in the process at step S11 without exposing the semiconductor substrate 5 to the atmosphere in the treatment chamber 31 in a vacuum-exhausted state as in the process at step S11. In the process at step S12, the Ge metal cell (metal cell using Ge as a metal material) 36 is heated to vaporize (sublimate) Ge atoms, and the front surface of the semiconductor substrate 5 is irradiated with the vaporized Ge atoms (vaporized particles) (hereinafter, referred to as Ge irradiation) 37. Since it is necessary to control the temperature of the Ge metal cell 36 in a range of about 1000 degrees C to 1500 degrees C, it is preferable to use, for example, electron beam heating capable of evaporating substantially all elements.

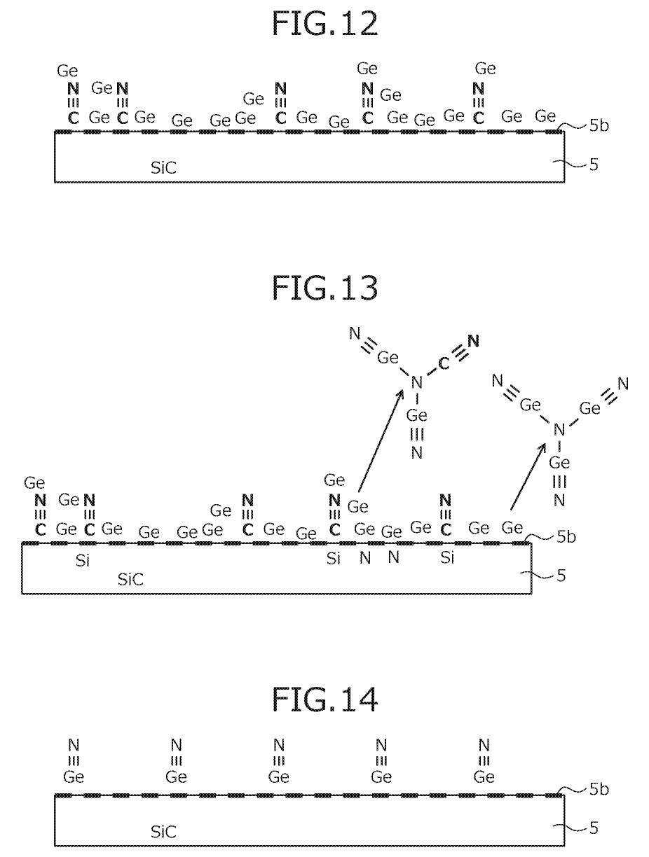

By the Ge irradiation 37, several atomic layers (for example, about 1 atomic layer to 5 atomic layers) of Ge atoms are deposited (vaporized) onto the front surface of the semiconductor substrate 5, and multiple Ge atoms are present in a vicinity of the cyano groups remaining at the front surface of the semiconductor substrate 5 (FIG. 12). The Ge atoms and the cyano groups at the front surface of the semiconductor substrate 5 are nitrided by the N radical irradiation 47. The Ge atoms are nitrided to become “—GeN groups (groups in which a Ge atom, N, and an atom are bonded by a triple bond: a second functional group) ”. The “—GeN group” moves on the front surface of the semiconductor substrate 5 by electromigration, collides with other nearby “—GeN groups” and nearby cyano groups, and forms molecules with these groups. Most “—GeN groups” will be Ge₃N₄ molecules with three “—GeN groups” joined by covalent bonds (single bonds) to the N atoms. The cyano group results in a Ge₂N₃—CN molecule connected to two “—GeN groups” by a covalent bond (single bond) to the N atom (FIG. 13).

These Ge₃N₄ molecules and Ge₂N₃—CN molecules are gaseous low molecules (gas molecules), stay (adsorb) at the surface for a short time, and are desorbed from the front surface of the semiconductor substrate 5. In FIG. 13, the desorption of molecules is schematically indicated by arrows. Therefore, by performing a set of the processes at steps S12 and S13 (Ge irradiation 37 and N radical irradiation 47) multiple times (step S14 (second removing process): NO in FIG. 3), the surface density of each of the “—GeN groups” and the cyano groups at the front surface of the semiconductor substrate 5 decreases. The “—GeN groups” and the cyano groups at the front surface of the semiconductor substrate 5 have the same mechanism of forming a low molecule and being eliminated. Therefore, the “—GeN group” and the cyano group have nearly the same maximum migration distance and nearly the same collision probability between the groups. All the cyano groups (groups containing excess carbon) at the front surface of the semiconductor substrate 5 are removed by collision with the “—GeN groups” newly generated by the processes at steps S12 and S13.

The “—GeN groups” at the front surface of the semiconductor substrate 5 do not collide with the neighboring “—GeN groups” every time the set of processes at steps S12 and S13 is performed, and remain at the front surface of the semiconductor substrate 5 at intervals of about the maximum migration distance of the “—GeN groups”, similarly to the behavior of the cyano groups at the front surface of the semiconductor substrate 5 during the process at step S11. The density of the “—GeN groups” remaining at the front surface of the semiconductor substrate 5 is about the same as the density of the cyano groups remaining at the front surface of the semiconductor substrate 5 after the process at step S11. At this time, the front surface of the semiconductor substrate 5 becomes the nitrided surface 5b by the “—GeN groups” in the portion where the “—GeN groups” remain, and the nitrided Si surface 5b is maintained in the portion between the “—GeN groups” adjacent to each other by repeating the process at step S13 (irradiation 47 of N radicals). Therefore, the entire front surface of the semiconductor substrate 5 is the nitrided surface 5b (broken line portion), and most of the front surface is the nitrided Si surface 5b (FIG. 14).

The number of times of performing the set of processes at steps S12 and S13 may be obtained in advance by, for example, simulation or the like such that all the cyano groups at the front surface of the semiconductor substrate 5 are substituted with the “—GeN groups”. On the other hand, when the gate insulating films 6 are deposited with Ge atoms (that is, “—GeN groups”) remaining at the front surface of the semiconductor substrate 5, an oxide containing the Ge atoms is generated at the interface between the gate insulating films 6 and the semiconductor substrate 5. The oxide containing the Ge atoms is an oxide in which a central metal atom (Si atom) of silicate ([SiO4]⁴⁻) constituting a siloxane bond (—Si—O—Si group) of the gate insulating films 6 is substituted with a Ge atom (Ge⁴⁺ ion). Since the oxide containing the Ge atoms easily allows electrons to flow (easily gives and receives and releases electrons: FIG. 15), an electron trap level is easily formed at the interface between the gate insulating films 6 and the semiconductor substrate 5, and adverse effects on the gate characteristics such as changes in gate threshold voltage and decreases in electron mobility may occur.

Therefore, after the removal of the cyano groups at the front surface of the semiconductor substrate 5 is completed (step S14 (second removing process) in FIG. 3: YES), it is preferable to reduce the density of Ge atoms at the front surface of the semiconductor substrate 5 by irradiating Mg atoms at the front surface of the semiconductor substrate 5 by a vacuum deposition method and depositing the Mg atoms (step S15 (third removing process) in FIG. 3). The process at step S15 may be performed continuously with the process at the last step S13 in the treatment chamber 31 in the same vacuum-exhausted state as the processes at steps S12 and S13. In the process at step S15, first, the temperature of the semiconductor substrate 5 is increased to a temperature within a range of about 1000 degrees C or more but not more than 1100 degrees C (for example, about 1070 degrees C). Next, Mg atoms (evaporated particles) vaporized (sublimated) by heating a metal cell 36 of Mg (a metal cell using Mg as a metal material) by, for example, electron beam heating, resistance heating, or the like are irradiated (hereinafter, referred to as Mg irradiation 38) onto the front surface of the semiconductor substrate 5, thereby depositing (evaporating) a layer of Mg atoms at the front surface of the semiconductor substrate 5.

Since the vapor pressure of Mg is very high, the flux amount necessary for the Mg irradiation 38 may be sufficiently obtained even when the metal cell 36 of Mg is heated to a temperature of about 350 degrees C to 450 degrees C by resistance heating. Therefore, resistance heating may be employed in the Mg irradiation 38, and the Mg metal cell 36 specialized for low-temperature control may be used. Generally, in a case of using a commercially available Mg metal cell 36, since the surface of the metal cell 36 is covered with a surface oxide or hydroxide, when the Mg metal cell 36 is heated to vaporize Mg atoms, flake-shaped particles scatter from the surface of the Mg metal cell 36. Therefore, before using the commercially available Mg metal cell 36, it is preferable to perform a purification treatment for removing surface oxides and hydroxides of the commercially available Mg metal cell 36. The flux amount necessary for the Mg irradiation 38 is, for example, in a range of about 1.0×10¹⁵/cm²sec to 5.0×10¹⁵/cm²sec.

The range of the flux amount of the Mg irradiation 38 described above is excessive to an extent that several layers of Mg atoms are deposited in one second in an instance in which all the irradiated Mg atoms are deposited on the front surface of the semiconductor substrate 5, however, the number of Mg atoms deposited on the front surface of the semiconductor substrate 5 is limited. Only one atomic layer of Mg atoms is deposited on the front surface of the semiconductor substrate 5 by one Mg irradiation 38. Excess Mg atoms (elemental Mg atoms) that are not deposited on the front surface of the semiconductor substrate 5 are evaporated (vaporized) due to an increase in vapor pressure at the heating temperature of the semiconductor substrate 5. When the semiconductor substrate 5 is heated to, for example, about 1070 degrees C, the vapor pressure of Mg atoms in a vicinity of the front surface of the semiconductor substrate 5 is about 1 atm (≈1×10⁵ Pa). Although not depicted in FIGS. 16 and 17 to be described later, evaporation of excess Mg atoms usually occurs during the process at step S15. The density of Mg atoms deposited on the front surface of the semiconductor substrate 5 does not exceed the density of N atoms at the front surface of the semiconductor substrate 5. When the entire front surface of the semiconductor substrate 5 is the nitrided surface 5b, the density of N atoms is about 10¹⁵ atoms/cm².

In the process at step S15, Mg atoms are excessively supplied at a supply amount exceeding the deposition amount (one atomic layer) of Mg atoms at the front surface of the semiconductor substrate 5 to promote reduction of the nitrided surface 5b (desorption of N atoms from the nitrided surface 5b), thereby reducing the density of Ge atoms at the front surface of the semiconductor substrate 5. Specifically, among the metal atoms (Ge atoms, Si atoms, and Mg atoms) present at the front surface of the semiconductor substrate 5 at the time of the process at step S15, the Mg atoms have higher electronegativity than the other metal atoms and have the highest binding energy (negative energy of electrons) with the N atoms than the other metal atoms (refer to FIG. 24). The nitrided surface 5b by the “—GeN groups” having the smallest binding energy with the N atom is reduced, and the N atom is desorbed from the nitrided surface 5b by the “—GeN groups”. The Mg atoms are bonded to the N atoms eliminated from the nitrided surface 5b by the “—GeN groups” to generate “—MgN groups (groups in which Mg atoms and N atoms are bonded by triple bonds)” and remain at the front surface of the semiconductor substrate 5. That is, the Mg atoms pull the shared electron pair from the nitrided surface 5b by the “—GeN groups” to increase the electron density (oxidation), become the “—MgN group” to be stabilized, and remain at the front surface of the semiconductor substrate 5 (FIG. 16). In FIG. 16, the moving direction of the N atom of the “—GeN groups” is schematically indicated by an arrow.

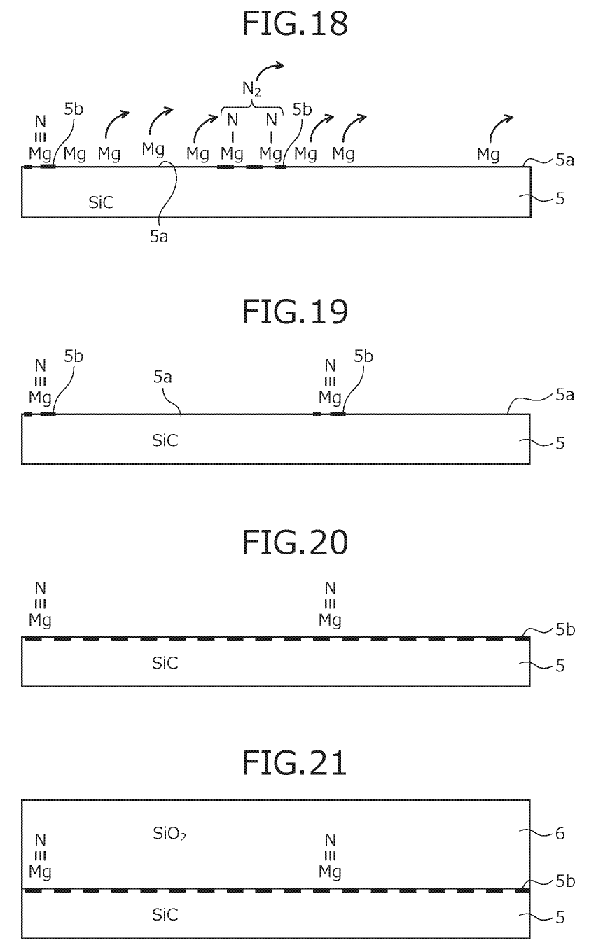

The elemental Ge atoms whose bond with the N atoms is broken by the reduction of the nitrided surface 5b by the “—GeN groups” increases in vapor pressure at the heating temperature of the semiconductor substrate 5 and evaporates (FIG. 17). In FIG. 17, the evaporation of elemental Ge atoms is schematically indicated by arrows. When the semiconductor substrate 5 is heated to, for example, about 1070 degrees C, the vapor pressure of Ge atoms in the vicinity of the front surface of the semiconductor substrate 5 is about 1 atm. When Mg atoms are excessively supplied beyond the deposition amount of Mg atoms at the front surface of the semiconductor substrate 5, the reduction of the nitrided surface 5b is promoted, and the nitrided Si surface 5b is also reduced. The nitrided Si surface 5b becomes a Si-rich surface 5a by breaking the bond with N atoms. The binding energy between N atoms is overwhelmingly larger than the binding energy between Mg atoms and N atoms (refer to FIG. 24). Therefore, when the “—MgN groups” collide with each other, N atoms of the “—MgN groups” are bonded to each other to form nitrogen (N₂₎ molecules (gaseous low molecules), which are desorbed from the front surface of the semiconductor substrate 5. The elemental Mg atoms whose bonds with the N atoms are broken are evaporated (vaporized) by the heating temperature of the semiconductor substrate 5 (FIG. 18). In FIG. 18, the evaporation of N₂ molecules and the evaporation of elemental Mg atoms are schematically indicated by arrows.

The evaporation of the elemental Ge atoms, the evaporation of the N₂ molecules, and the evaporation of the elemental Mg atoms by the reduction of the nitrided surface 5b described above continue until the collision between the “—MgN groups” does not occur, and the ”—MgN groups” remain at the front surface of the semiconductor substrate 5 at intervals to the extent that the collision between the “—MgN groups” does not occur. The front surface of the semiconductor substrate 5 becomes a Si-rich surface 5a except for a portion where the “—MgN group ” remains (FIG. 19). Even when Mg atoms are excessively supplied to the front surface of the semiconductor substrate 5, the density of Mg atoms remaining at the front surface of the semiconductor substrate 5 is about 1×10¹¹ atoms/cm² or more but not more than 1×10¹³ atoms/cm². The supply amount of Mg atoms per unit time to the front surface of the semiconductor substrate 5 may be controlled by alternately repeating the Mg irradiation 38 (supply of Mg atoms) and the pause of the Mg irradiation 38 (non-supply of Mg atoms) multiple times according to the reduction rate of the nitrided surface 5b. For example, when a set of Mg irradiation 38 for 2 seconds with a flux amount of 5.0×10¹⁵/cm²sec and a pause of Mg irradiation 38 for 20 seconds is performed five times, the total density of Mg atoms irradiated to the front surface of the semiconductor substrate 5 is about 5×10¹⁶ atoms/cm², and the density of Mg atoms remaining at the front surface of the semiconductor substrate 5 is about 2×10¹² atoms/cm².

Therefore, the irradiation conditions of the Mg irradiation 38, the pause time of the Mg irradiation 38, and the number of times of performing a set of the Mg irradiation 38 and the pause of the Mg irradiation 38 may be obtained in advance by, for example, simulation or the like such that the “—MgN groups” remain at the front surface of the semiconductor substrate 5 at intervals at which the “—MgN groups” do not collide with each other. Although Ge atoms remain at a constant density at the front surface of the semiconductor substrate 5 even after the process at step S15, the density of Ge atoms at the front surface of the semiconductor substrate 5 may be reduced to such an extent that gate characteristics are not adversely affected even when the Ge atoms become electron trap levels (not depicted in FIGS. 18 to 21). The density of N atoms remaining at the front surface of the semiconductor substrate 5 after the process at step S15 is presumed to be the same as the density of Mg atoms (density of “—MgN groups”) remaining at the front surface of the semiconductor substrate 5 after the process at step S15. Therefore, at the front surface of the semiconductor substrate 5 after the process at step S15, the density of N atoms is estimated to be lower than a total combined density of Si atoms, Ge atoms, and Mg atoms by about three orders of magnitude, and the front surface becomes the Si-rich surface 5a in a relatively wide area. In the process at step S15, instead of the Mg irradiation 38, other alkaline earth metal atoms such as calcium (Ca), strontium (Sr), or barium (Ba) may be irradiated and deposited on the front surface of the semiconductor substrate 5.

When the density of N atoms at the front surface of the semiconductor substrate 5 is relatively low, the front surface of the semiconductor substrate 5 is easily activated, and adsorption of a trace amount of gas to the front surface of the semiconductor substrate 5 easily occurs. Therefore, the Si-rich surface 5a of the front surface of the semiconductor substrate 5 is changed to the nitrided Si surface 5b by the N radical irradiation 47 to the front surface of the semiconductor substrate 5, whereby the entire front surface of the semiconductor substrate 5 is nitrided and inactivated (passivated) (step S16 in FIG. 3, FIG. 20). In the process at step S16, for example, the N radical irradiation 47 is performed for about 20 seconds by the same method and under the same conditions as those of the process at step S11, for example, with a flux amount of about 1.0×10¹⁵/cm²sec, without exposing the semiconductor substrate 5 to the atmosphere in the treatment chamber 31 in the same evacuated state as that of the process at step S15. In the process at step S16, instead of the N radical irradiation 47, the front surface of the semiconductor substrate 5 may be nitrided by heat treatment under the same conditions as in the process at step S5 described later.

Next, an oxide film (SiO₂₎ constituting the gate insulating films 6 is deposited on the front surface of the semiconductor substrate 5 (step S4 in FIG. 2, FIG. 7 (first forming process)). In the process at step S4, for example, a high temperature oxide (HTO) layer may be deposited as the gate insulating films 6 by a low-pressure chemical vapor deposition (LPCVD) method. Alternatively, the gate insulating films 6 may be deposited by a vacuum deposition method without exposing the semiconductor substrate 5 to the atmosphere in the treatment chamber 31 in a vacuum-exhausted state as in the process at step S16. In this case, the vacuum apparatus 30 (refer to FIG. 22) further includes an evaporation source (not depicted) of Si and a radical generator (radical source: not depicted) for generating atomic oxygen (O) radicals in the treatment chamber 31. The radical generator 40 (refer to FIG. 23) of the vacuum apparatus 30 may have a function of generating multiple types of radicals. The method of generating O radicals is the same as the method of generating N radicals except that O₂ gas is used as the source gas.

During the process at step S4, since all the excess carbon at the front surface of the semiconductor substrate 5 is removed in advance by the process at step S3 described above, crystal defects caused by the excess carbon do not occur at the interface between the gate insulating films 6 and the semiconductor substrate 5. In the process at step S4, Ge atoms (“—GeN groups”: not depicted) and Mg atoms (“—MgN groups”) remaining at the front surface of the semiconductor substrate 5 are taken into the gate insulating films 6 (FIG. 21). Since the density of Ge atoms remaining at the front surface of the semiconductor substrate 5 is as low as about 1×10⁸ atoms/cm² or more but not more than 1×10¹² atoms/cm², even when Ge atoms at the interface between the gate insulating films 6 and the semiconductor substrate 5 become an electron trap level, gate characteristics are not adversely affected. The density of Mg atoms remaining at the front surface of the semiconductor substrate 5 is relatively high. However, the Mg atoms are changed into an oxide (MgO) by the treatment at step S5 described later and heat treatment and thermal history in the subsequent steps, and the band gap becomes large, and electrons hardly flow. Therefore, Mg atoms at the interface between the gate insulating films 6 and the semiconductor substrate 5 do not become a trap level. The thickness of the gate insulating films 6 is, for example, about 50 nm.

Next, in a heat treatment furnace, the interface between the gate insulating films 6 and the semiconductor substrate 5 is oxynitrided by a heat treatment (oxynitriding annealing) under an atmospheric pressure atmosphere at, for example, about 1150 degrees C or more but not more than 1300 degrees C using a gas containing N atoms and oxygen (O) atoms (for example, a mixed gas of 90% N₂ gas and 10% N₂O gas) (step S5 (heat treatment step) in FIG. 2). By the process at step S5, the interface (nitrided surface 5b) between the gate insulating films 6 and the semiconductor substrate 5 and the “—GeN groups” and the “—MgN group” at the interface between the gate insulating films 6 and the semiconductor substrate 5 are assimilated with the gate insulating films 6. The “—GeN groups” at the interface between the gate insulating films 6 and the semiconductor substrate 5 changes to an oxide or an oxynitride in the gate insulating films 6. The “—MgN group” at the interface between the gate insulating films 6 and the semiconductor substrate 5 is thermally decomposed, and Mg atoms and N atoms are respectively changed to oxides. The Mg atoms change into an oxide (magnesium oxide (MgO)) in the gate insulating films 6, and the oxide (gas) of the N atoms evaporates and is exhausted to the outside of the heat treatment furnace.

Next, the gate electrodes 7 are formed on the surface of the gate insulating films 6 (step S6 (second forming step) in FIG. 2). In the process at step S6, a polysilicon layer is deposited by a general deposition method such as LPCVD, and the polysilicon layer is patterned thereby leaving portions constituting the gate electrodes 7. A gate polysilicon wiring layer functioning as a gate finger may be formed by extending a part of the polysilicon layer to a region other than the active region. Next, the interlayer insulating film 8 is formed on the entire front surface of the semiconductor substrate 5. Next, the contact holes 8a and 8b penetrating through the interlayer insulating film 8 and the gate insulating films 6 in the depth direction and the contact holes 8c penetrating through the interlayer insulating film 8 in the depth direction are formed.

Next, an aluminum (Al) film or an Al alloy film is formed on the front surface of the semiconductor substrate 5 and patterned to form the source electrode 13, the drain electrode 14, the gate metal wiring layer 15, and a gate pad (not depicted) as front electrodes (step S7 in FIG. 2). The source electrode 13 is electrically connected to the n⁺-type source regions 3 via the contact holes 8a. The drain electrode 14 is electrically connected to the n⁺-type drain regions 4 via the contact holes 8b. The gate polysilicon wiring layer is formed on the front surface of the semiconductor substrate 5 via a field oxide film (not depicted). The gate metal wiring layer 15 is formed on the gate polysilicon interconnection layer in contact holes 8c, and functions as a gate finger.

The field oxide film may be formed at any timing before the interlayer insulating film 8 is formed. The interlayer insulating film 8 may also serve as a field oxide film. Thereafter, the entire front surface of the semiconductor substrate 5 is covered with a passivation film (not depicted) for protection. Then, the passivation film is partially removed by photolithography and etching to expose portions to be electrode pads (a source pad, a drain pad, and a gate pad) in different openings of the passivation film, thereby completing silicon carbide semiconductor device 10 (planar MOSFET) depicted in FIG. 1. A portion of the source electrode 13 exposed in the opening of the passivation film functions as a source pad. A portion of the drain electrode 14 exposed in the opening of the passivation film functions as a drain pad.

In the method of manufacturing the silicon carbide semiconductor device according to the above-described embodiment, a vertical MOSFET having a planar gate structure may be fabricated instead of the planar MOSFET. In this case, the epitaxial layers 11 and 12 constituting the n⁻-type region 1 and the p-type region 2 are grown by epitaxy on the front surface of an n⁺-type starting substrate constituting an n⁺-type drain region during the process at step S1, and the drain electrode is formed at the back surface of the n⁺-type starting substrate during the process at step S7. The n⁺-type drain region may be formed by ion implantation of an n-type dopant at the back surface of the semiconductor substrate 5 before the process at step S7. In this method of manufacturing a vertical MOSFET, a trench gate structure may be formed instead of the planar gate structure.

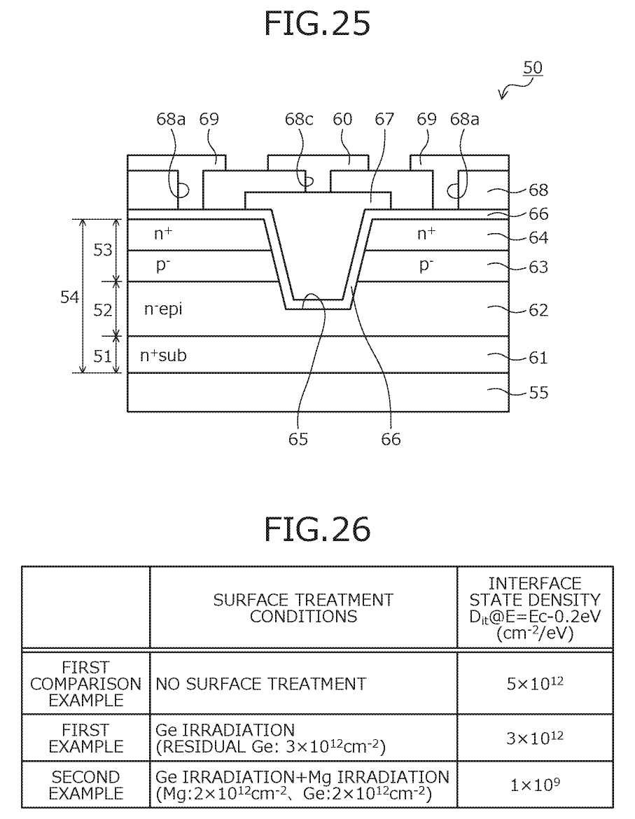

FIG. 25 is a cross-sectional view depicting another example of a structure of a silicon carbide semiconductor device according to the embodiment. A silicon carbide semiconductor device 50 according to the embodiment depicted in FIG. 25 is a vertical MOSFET having a trench gate structure to which the structure of the silicon carbide semiconductor device 10 according to the embodiment depicted in FIG. 1 is applied, and includes a trench gate structure in which a gate electrode 67 is embedded in a trench 65 formed in a semiconductor substrate 54, at a front surface thereof via a gate insulating film 66. The semiconductor substrate 54 is a semiconductor chip formed by growing by epitaxy epitaxial layers 52 and 53 constituting an n⁻-type drift region (first semiconductor region) 62 and a p⁻-type base region (second semiconductor region) 63 in this order on a front surface of an n⁺-type starting substrate (bulk substrate) 51 containing SiC.

The semiconductor substrate 54 has, as a front surface, a first main surface having the epitaxial layer 53 and, as a back surface, a second main surface having the n⁺-type starting substrate 51. The n⁺-type starting substrate 51 constitutes an n⁺-type drain region 61. An n⁺-type source region (third semiconductor regions) 64 and a p⁺-type contact region (not depicted) are each selectively provided between the front surface of the semiconductor substrate 54 and the p⁻-type base region 63 so as to be exposed at the front surface of the semiconductor substrate 54 and in contact with the p⁻-type base region 63. The n⁺-type source region 64 and the p⁺-type contact region are diffused regions formed by ion implantation in the epitaxial layer 53. A portion of the p-type epitaxial layer 53 excluding the n⁺-type source region 64 and the p⁺-type contact region constitutes the p⁻-type base region 63.

The trench 65 penetrates through the n⁺-type source region 64 and the p⁻-type base region 63 from the front surface of the semiconductor substrate 54 and terminates in the n⁻-type drift region 62. The trench 65 preferably has a substantially tapered cross-sectional shape in which the width thereof decreases in a direction from the opening side to the bottom surface. Since each sidewall of the trench 65 is inclined so as to form an obtuse angle with respect to the bottom surface of the trench 65, it is possible to increase the flux amount per unit time of the N radical irradiation 47, the Ge irradiation 37, and the Mg irradiation 38 (refer to FIG. 6) with respect to the sidewalls of the trench 65 during the process at step S3 described above, as compared with a case where the sidewalls and the bottom surface of the trench 65 form a substantially right angle. A gate insulating film 66 is provided along the inner wall (sidewalls and bottom surface) of the trench 65.

The configuration of the gate insulating film 66 is the same as that of the gate insulating films 6 in FIG. 1 except that the gate insulating film 66 is provided along the inner wall of the trench 65. The configuration of the interface between the gate insulating film 66 and the semiconductor substrate 54 is the same as that of the interface between the gate insulating films 6 and the semiconductor substrate 5 in FIG. 1. That is, Ge atoms and Mg atoms are present at the interface between the gate insulating film 66 and the semiconductor substrate 54. Ge atoms at the interface between the gate insulating film 66 and the semiconductor substrate 54 form an oxide or an oxynitride in the gate insulating film 66 and are assimilated with the gate insulating film 66. The Mg atoms at the interface between the gate insulating film 66 and the semiconductor substrate 54 form an oxide in the gate insulating film 66 and are assimilated with the gate insulating film 66. The interface between the gate insulating film 66 and the semiconductor substrate 54 is an interface between the gate insulating film 66 and the inner wall (SiC surface) of the trench 65 and an interface between the gate insulating film 66 and the front surface (SiC surface) of the semiconductor substrate 54.

The gate electrode 67 is provided on the gate insulating film 66 in the trench 65. The gate electrode 67 may protrude upward from the inside of the trench 65. The configuration of the gate electrode 67 is the same as that of the gate electrodes 7 in FIG. 1 except that the gate electrode 67 is embedded in the trench 65. The interlayer insulating film 68 is provided on the entire front surface of the semiconductor substrate 54 and covers the gate electrode 67. The configurations of the interlayer insulating film 68, the contact holes 68a and 68c, the source electrode 69, the gate metal wiring layer 60, and the gate pad (not depicted) are the same as those of the interlayer insulating film 8, the contact holes 8a and 8c, the source electrode 13, the gate metal wiring layer 15, and the gate pad (not depicted) in FIG. 1. The drain electrode 55 is provided on the entire back surface of the semiconductor substrate 54 and is electrically connected to the n⁺-type drain region 61.

In the method of manufacturing the silicon carbide semiconductor device 50 according to the embodiment depicted in FIG. 25, in the method of manufacturing the silicon carbide semiconductor device 10 according to the embodiment depicted in FIG. 1 described above (refer to FIGS. 2 and 3), after the process at step S1 (formation of the n⁺-type source region 64 and the p⁺-type contact region), the trench 65 may be formed, and then the processes at steps S2 to S7 may be performed as described above. To form the trench 65, first, an oxide film (SiO₂₎ constituting an etching mask is deposited on the front surface of the semiconductor substrate 5 by, for example, a CVD method, and a portion of the oxide film corresponding to a formation region of the trench 65 is opened by photolithography and dry etching using, for example, a mixed gas containing a trifluoromethane (CHF₃₎ gas, a CF₄ gas, and an Ar gas. Then, the resist mask used for the opening of the oxide film is removed.

The oxide film is used as a mask to form the trench 65 by dry etching using a mixed gas containing sulfur hexafluoride (SF₆₎ gas, O₂ gas, and Ar gas by an ICP etching equipment, for example. Then, the oxide film used as the etching mask is removed by, for example, hydrofluoric acid (HF). After the removal of the oxide film used as the etching mask but before the process at step S2, a heat treatment for controlling the cross-sectional shape of the trench 65 may be performed. In the process at step S2, the inner wall of the trench 65 and the front surface of the semiconductor substrate 54 are cleaned by the etching 22 or the like (refer to FIG. 5). In the process at step S3, N radical irradiation 47, Ge irradiation 37, and Mg irradiation 38 are performed on the inner wall of the trench 65 and the front surface of the semiconductor substrate 54 (refer to FIGS. 3 and 6).

In the N radical irradiation 47, the Ge irradiation 37, and the Mg irradiation 38, the flux amount per unit time to the sidewalls (surfaces inclined with respect to the front surface of the semiconductor substrate 54) of the trench 65 is smaller than the flux amount per unit time to the front surface of the semiconductor substrate 54. Therefore, in the case of forming the trench gate structure, the irradiation time is increased as compared with the case of manufacturing the planar MOSFET. Predetermined irradiation amounts of the N radical irradiation 47, the Ge irradiation 37, and the Mg irradiation 38 to the sidewalls of the trench 65 may be ensured. In the process at step S4, the gate insulating film 66 is deposited from the inner wall of the trench 65 to the front surface of the semiconductor substrate 54. In the process at step S6, a trench gate structure is formed by embedding in the trench 65 the gate electrode 67, via the gate insulating film 66.

As described above, according to the embodiment, all excess carbon deposited on the surface of the semiconductor substrate is removed in advance before the gate insulating film is deposited. The excess carbon deposited on the surface of the semiconductor substrate may be easily removed by utilizing recombination of bonds between the excess carbon, N atoms irradiated to the surface of the semiconductor substrate, and Ge atoms deposited on the surface of the semiconductor substrate, and an electromigration phenomenon. At the interface between the gate insulating film and the semiconductor substrate of the product (silicon carbide semiconductor device), Ge atoms remain instead of excess carbon, and there is no excess carbon. Since there is no excess carbon that becomes a hole trap level at the interface between the gate insulating film and the semiconductor substrate, decreases in channel mobility may be prevented.

Further, according to the embodiment, before the gate insulating film is deposited, the density of Ge atoms remaining at the surface of the semiconductor substrate is reduced to such an extent that the gate characteristics are not adversely affected even when the Ge atoms remaining at the interface between the gate insulating film of the product and the semiconductor substrate become an electron trap level. Ge atoms remaining at the surface of the semiconductor substrate may be easily reduced by utilizing recombination of bonds between the Ge atoms, N atoms bonded to Si atoms or Ge atoms at the surface (nitrided surface) of the semiconductor substrate, and Mg atoms deposited on the surface of the semiconductor substrate, and an oxidation-reduction reaction due to a binding energy difference. Since the density of Ge atoms at the interface between the gate insulating film and the semiconductor substrate is reduced to such an extent that the gate characteristics are not adversely affected, the reliability of the silicon carbide semiconductor device may be improved.

According to the embodiment, Ge atoms and Mg atoms present at the interface between the gate insulating film and the semiconductor substrate are incorporated into the gate insulating film and assimilated with the gate insulating film. Therefore, the insulating property of the gate insulating film is maintained. The Mg atoms at the interface between the gate insulating film and the semiconductor substrate become an oxide in the gate insulating film and have a large band gap. Since the Mg atoms hardly pass electrons, the Mg atoms do not become a trap level. Therefore, increases in the interface state density at the interface between the gate insulating film and the semiconductor substrate may be prevented.

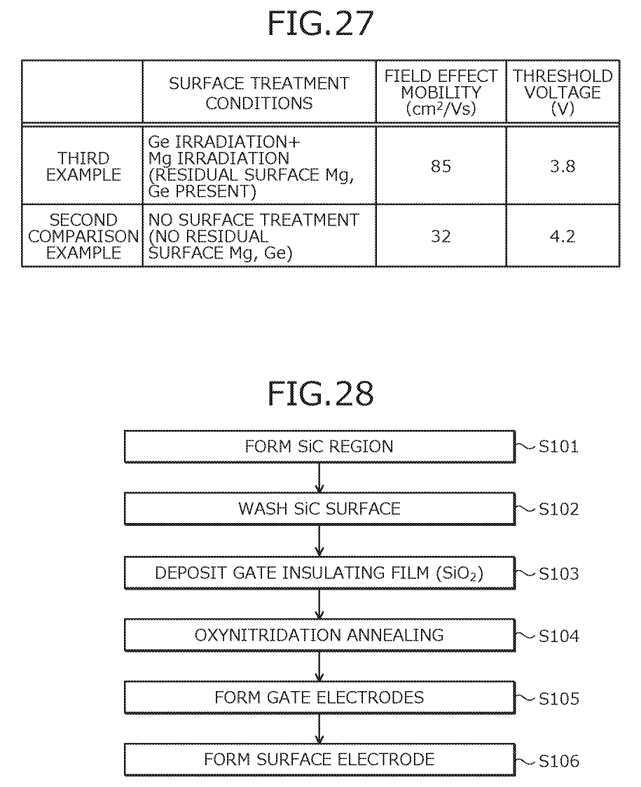

The effect of the process (cleaning of the SiC surface) at step S3 of the method of manufacturing the silicon carbide semiconductor device according to the above-described embodiment (refer to FIGS. 2 and 3) was verified using a general MOS capacitor (not depicted). FIG. 26 is a table depicting the results of measuring the interface state density at the SiO_{2/}SiC interface in the first and second examples and the first comparison example. FIG. 27 is a table depicting results of calculation of field-effect mobilities of a third example and a second comparison example by simulation. According to the method of manufacturing the silicon carbide semiconductor device 10 according to the embodiment described above, MOS capacitors (hereinafter referred to as the first and second examples) were fabricated on an n-type SiC substrate.

The SiC substrate is an epitaxial substrate formed by depositing an n-type epitaxial layer having a thickness of 5 μm on a front surface of a bulk substrate containing 4H—SiC (four-layer periodic hexagonal crystal of silicon carbide) after flattening the front surface by chemical mechanical polishing (CMP). The front surface of the SiC substrate is a (0001) plane having an off angle of about 4 degrees in a <11-20> direction, that is, a so-called Si plane. A gate insulating film and an Al gate electrode layer were deposited in this order on the front surface (main surface on the epitaxial layer side) of the SiC substrate, and an Al electrode layer was deposited on the back surface (main surface on the bulk substrate side) of the SiC substrate.

The SiC substrate, the gate insulating film, and the Al gate electrode layer of the first and second examples correspond to the semiconductor substrate 5, the gate insulating films 6, and the gate electrode 7 in FIG. 1, respectively. The first and second examples were manufactured by performing RCA cleaning and H₂ etching (corresponding to the processes at steps S1 and S2 in FIG. 2) on the front surface (SiC surface) of the SiC substrate and thereby removing excess carbon at the SiC surface by cleaning the SiC surface (corresponding to the process at step S3 in FIG. 2), depositing a gate insulating film on the SiC surface (corresponding to the process at step S4 in FIG. 2), and performing oxynitride annealing, vapor deposition of an Al gate electrode layer, and vapor deposition of an Al electrode layer (corresponding to the processes at steps S5 to S7 in FIG. 2).

In the first and second examples, the process conditions at steps S2 and S4 to S7 are the same, and the process condition at step S3 (surface process condition for cleaning the SiC surface) is different. The H₂ etching in the process at step S2 was performed for 5 minutes at a H₂ gas pressure of 700 Pa and a SiC substrate temperature of 1450 degrees C. In the first example, the process at step S3 corresponds to the processes at steps S11 to S14 in FIG. 3, and the processes at steps S15 and S16 in FIG. 3 were not performed (surface treatment condition: Ge irradiation). In the second example, the processes at steps S11 to S16 in FIG. 3 were performed in the process at step S3 (surface treatment condition: Ge irradiation +Mg irradiation).

In the process at step S4 (deposition of the gate insulating film), HTO having a thickness of about 50 nm was deposited as the gate insulating film by LPCVD using a mixed gas of SiH₄ gas and O₂ gas as a film forming gas, setting the pressure in the treatment chamber to 0.2 Pa, and setting the temperature of the SiC substrate to 600 degrees C. The treatment at step S5 (oxynitriding annealing) was performed at a temperature of 1200 degrees C for 60 minutes in an atmospheric pressure atmosphere using a mixed gas of 90% N₂ gas and 10% NO gas. The processes at steps S6 and S7 (formation of the electrode layer) were performed using a vacuum deposition method by resistance heating. The Al gate electrode layer was formed into a circular planar shape having a diameter of 200 μm using a metal mask.

The first comparison example is a MOS capacitor fabricated according to the method of manufacturing the silicon carbide semiconductor device of the reference example (refer to FIG. 28). In the first comparison example, the conditions are the same as those in the first and second examples except that the treatment at step S3 is not performed (surface treatment conditions: no surface treatment). The process conditions at steps S102 to S106 of the first comparison example are the same as the process conditions at steps S2 and S4 to S7 of the first and second examples, respectively. The interface state density of the SiO_{2/}SiC interface (interface between the gate insulating film and the SiC substrate) in FIG. 26 was calculated by the high-low C-V method using the high-frequency C-V characteristics at 1 MHz and the low-frequency C-V characteristics at 100 Hz based on the measured values of the first and second examples and the first comparison example.

As depicted in FIG. 26, in the first and second examples, Ge atoms due to Ge irradiation (corresponding to the process at step S12) remained at the SiO₂/SiC interface, but the interface state density (crystal defect density) at the SiO2/SiC interface was reduced as compared with the first comparison example in which Ge irradiation was not performed. In the second example, Ge atoms due to Mg irradiation (corresponding to the process at step S15) remain at the SiO₂/SiC interface. However, the density of Ge atoms remaining at the SiO₂/SiC interface was lower than that in the first example in which Mg irradiation was not performed, and the interface state density at the SiO₂/SiC interface was lower than that in the first example.

Therefore, it was confirmed that all excess carbon on the SiC surface may be removed by the processes at steps S11 to S14 of the method of manufacturing the silicon carbide semiconductor device 10 according to the embodiment (refer to FIG. 3), and the interface state density at the SiO_{2/}SiC interface may be reduced. Further, it was confirmed that the Ge atoms remaining at the SiO₂/SiC interface may be reduced by the process at step S15 of the method of manufacturing the silicon carbide semiconductor device 10 according to the embodiment, and the interface state density at the SiO₂/SiC interface may be further reduced.

Based on the interface state densities of the SiO_{2/}SiC interfaces of the second example and the first comparison example described above, the field-effect mobilities of planar MOSFETs (hereinafter referred to as the third example and the second comparison example) having the structure of silicon carbide semiconductor device 10 according to the embodiment depicted in FIG. 1 were calculated. The results are depicted in FIG. 27. The third example and the second comparison example include insulated gate structures formed under the same conditions as the second example and the first comparison example described above, respectively. In the third example, the semiconductor substrate 5 is formed by growing by epitaxy the n⁻-type epitaxial layer 11 that constitutes the n⁻-type region 1 and a p-type epitaxial layer 12 that constitutes the p-type region 2 in this order on a front surface of a 4H—SiC substrate that is a starting substrate.

The front surface of the 4H—SiC substrate is a (0001) plane having an off angle of about 4 degrees in the <11-20> direction. The dopant of the epitaxial layer 11 is nitrogen (N). The dopant and acceptor concentrations N_{A} of the p-type epitaxial layer 12 are aluminum (Al) and 1×10¹⁶/cm³, respectively. The n⁺-type source regions 3 and the n⁺-type drain regions 4 are SiC regions formed by ion implantation of phosphorus (P) into the epitaxial layer 12. RCA cleaning and HF cleaning were performed on the SiC surface (the surface of the 4H—SiC substrate and the exposed surfaces of the epitaxial layers 11 and 12) between various steps such as epitaxial growth and dopant ion implantation (corresponding to step S1 in FIG. 2).

The treatment at step S2 in FIG. 2 and the treatment at step S3 in FIG. 3 (surface treatment conditions: Ge irradiation 37 +Mg irradiation 38) were performed on the front surface (SiC surface: surface on the epitaxial layer 12 side) of the semiconductor substrate 5 in the same manner as in the second example, and then the gate insulating films 6 were deposited (corresponding to step S4 in FIG. 2). Therefore, in the third example, similarly to the second example, Mg atoms and Ge atoms remain at the interface (SiO_{2/}SiC interface) between the gate insulating films 6 and the semiconductor substrate 5. After the oxynitride annealing, gate electrodes 7 were deposited on the gate insulating films 6. The conditions of the deposition of the gate insulating films 6 and the oxynitride annealing (corresponding to steps S4 and S6 in FIG. 2) are the same as those in the second embodiment.

The gate electrodes 7 are formed by a polysilicon layer having a thickness of 50 nm deposited by LPCVD. The interlayer insulating film 8 was deposited on the front surface of the semiconductor substrate 5 so as to cover the gate electrodes 7. The interlayer insulating film 8 is a SiO₂ film having a thickness of 700 nm deposited by a plasma-enhanced chemical vapor deposition (PECVD) method. Contact holes 8a to 8c were formed in interlayer insulating film 8 by photolithography and dry etching using boron trichloride (BCl₃₎ gas by ICP etching equipment or wet etching using a buffered hydrofluoric acid (BHF) solution.

Al electrode films were deposited as the source electrode 13, the drain electrode 14, and the gate metal wiring layer 15 so as to be embedded in the contact holes 8a to 8c, respectively (corresponding to step S7 in FIG. 2). The source electrode 13 and the drain electrode 14 include a nickel silicide film as an ohmic electrode film and a Ti film as a barrier metal between the Al electrode film and the semiconductor substrate 5. In the second comparison example, similarly to the first comparison example, the treatment at step S3 depicted in FIG. 2 was not performed (surface treatment condition: no surface treatment), and Mg atoms and Ge atoms were not present at the SiO_{2/}SiC interface. In the second comparison example, the conditions other than the state of the SiO_{2/}SiC interface were the same as those in the third example.

As depicted in FIG. 27, a peak value (maximum value) of the field-effect mobility in the third example was significantly larger than that in the second comparison example. It was confirmed that the reduction of the interface state density at the SiO_{2/}SiC interface (refer to FIG. 26) greatly contributes to the improvement of the field-effect mobility.

As described above, the present disclosure is not limited to the above-described embodiments and various modifications within a range not departing from the spirit of the present disclosure are possible. In the embodiments, the first conductivity type is an n-type and the second conductivity type is a p-type. However, the present disclosure is further applicable to a case where the first conductivity type is a p-type, and the second conductivity type is an n-type. Further, in each of the embodiments, while the description has been given using the MOSFET, the same applies to an IGBT.

According to the silicon carbide semiconductor device and the method of manufacturing a silicon carbide semiconductor device according to the present disclosure, excess carbon at the interface between the gate insulating film and the semiconductor substrate may be removed.

As described above, the silicon carbide semiconductor device and the method of manufacturing a silicon carbide semiconductor device according to the present disclosure are useful for power semiconductor devices used for power conversion devices, a power supply devices for various industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate containing silicon carbide;
a gate insulating film containing silicon oxide, provided on a surface of the semiconductor substrate; and
a gate electrode provided on a surface of the gate insulating film, wherein
the semiconductor device has a plurality of germanium atoms and a plurality of alkaline earth metal atoms at an interface between the gate insulating film and the semiconductor substrate.

2. The silicon carbide semiconductor device according to claim 1, wherein a density of the plurality of germanium atoms at the interface between the gate insulating film and the semiconductor substrate is not less than 1×10⁸ atoms/cm² but not more than 1×10¹² atoms/cm².

3. The silicon carbide semiconductor device according to claim 1, wherein a density of the plurality of alkaline earth metal atoms at the interface between the gate insulating film and the semiconductor substrate is not less than 1×10¹¹ atoms/cm² but not more than 1×10¹³ atoms/cm².

4. The silicon carbide semiconductor device according to claim 1, wherein the plurality of germanium atoms at the interface between the gate insulating film and the semiconductor substrate constitute an oxide or an oxynitride in the gate insulating film.

5. The silicon carbide semiconductor device according to claim 1, wherein the plurality of alkaline earth metal atoms at the interface between the gate insulating film and the semiconductor substrate constitute an oxide in the gate insulating film.

6. The silicon carbide semiconductor device according to claim 1, wherein the interface between the gate insulating film and the semiconductor substrate is free of excess carbon.

7. The silicon carbide semiconductor device according to claim 1, further comprising:
a first semiconductor region of a first conductivity type, provided in the semiconductor substrate; a second semiconductor region of a second conductivity type, provided in the semiconductor substrate and between the surface of the semiconductor substrate and the first semiconductor region; and a third semiconductor region of the first conductivity type, selectively provided in the semiconductor substrate and between the surface of the semiconductor substrate and the second semiconductor region, wherein
the second semiconductor region has a region between the third semiconductor regions and the first semiconductor region, said region being in contact with the gate insulating film, and the gate electrode is provided facing the second semiconductor region with the gate insulating film intervening therebetween.

8. The silicon carbide semiconductor device according to claim 1, wherein the plurality of alkaline earth metal atoms is a plurality of magnesium atoms.

9. A method of manufacturing a silicon carbide semiconductor device, the method comprising:
as a predetermined process, preparing a semiconductor substrate containing silicon carbide and oxidizing a surface of the semiconductor substrate, a plurality of carbon atoms being deposited on the surface of the semiconductor substrate in the predetermined process; as a removing process, removing the plurality of carbon atoms; as a first forming process, depositing a gate insulating film containing silicon oxide on the surface of the semiconductor substrate from which the plurality of carbon atoms has been removed; and as a second forming process, forming a gate electrode on a surface of the gate insulating film, wherein the removing process includes:
as a first removing process, performing a first irradiation to the surface of the semiconductor substrate with a first plurality of nitrogen atoms having unpaired electrons, thereby desorbing the plurality of carbon atoms from the surface of the semiconductor substrate, and as a second removing process, performing
a first process of depositing a plurality of germanium atoms on the surface of the semiconductor substrate, and
a second process of performing a second irradiation to the surface of the semiconductor substrate with a second plurality of nitrogen atoms having unpaired electrons, thereby desorbing remaining ones of the plurality of carbon atoms at the surface of the semiconductor substrate after the first removing process.

10. The method of manufacturing according to claim 9, wherein the first removing process includes heating the semiconductor substrate at a temperature of not less than 500 degrees C but not more than 800 degrees C.

11. The method of manufacturing according to claim 9, wherein the second removing process includes heating the semiconductor substrate at a temperature of not less than 500 degrees C but not more than 800 degrees C.

12. The method of manufacturing according to claim 9, wherein the second removing process includes performing, as a set, the first process and the second process a plurality of times and thereby setting a density of the plurality of germanium atoms remaining at the surface of the semiconductor substrate to be within a range not less than 1×10¹¹ atoms/cm² but not more than 1×10¹² atoms/cm².

13. The method of manufacturing according to claim 9, wherein the removing process further includes a third removing process of depositing a plurality of alkaline earth metal atoms on the surface of the semiconductor substrate after the second removing process, thereby removing the plurality of germanium atoms at the surface of the semiconductor substrate.

14. The method of manufacturing according to claim 13, wherein the plurality of alkaline earth metal atoms is a plurality of magnesium atoms.

15. The method of manufacturing according to claim 14, wherein the third removing process includes supplying the plurality of magnesium atoms to the surface of the semiconductor substrate in a supply amount exceeding a deposition amount of the plurality of magnesium atoms at the surface of the semiconductor substrate.

16. The method of manufacturing according to claim 14, wherein the third removing process includes heating the semiconductor substrate at a temperature of not less than 1000 degrees C but not more than 1100 degrees C.

17. The method of manufacturing according to claim 9, further comprising, after the first forming process but before the second forming process, a heat treatment of oxynitriding an interface between the gate insulating film and the semiconductor substrate.

18. The method of manufacturing according to claim 14, wherein
in the first removing process, a first functional group is desorbed from the surface of the semiconductor substrate by an electromigration of the first functional group due to a covalent bond between the plurality of carbon atoms and the plurality of nitrogen atoms subjected to the first irradiation, and in the second removing process, a second functional group is desorbed from the surface of the semiconductor substrate by an electromigration of the second functional group due to a covalent bond between the plurality of germanium atoms and the plurality of nitrogen atoms subjected to the second irradiation.

19. The method of manufacturing according to claim 18, wherein in the third removing process, the second functional group is reduced by the plurality of magnesium atoms, thereby evaporating and removing ones of the plurality of germanium atoms whose bonds with the plurality of nitrogen atoms are broken.
